(19) United States
(12) Patent Application Publication
(10) Pub. No.: US 2012/0037787 A1
(43) Pub. Date: Feb. 16, 2012

(54) IMAGE SENSOR

(75) Inventors: Takashi Kitada, Fukuoka (JP); Masahiro Inoue, Fukuoka (JP); Shinichiro Kaneko, Fukuoka (JP); Takahiro Komatsu, Fukuoka (JP); Masakazu Mizusaki, Fukuoka (JP); Yasuyuki Takano, Fukuoka (JP)

(73) Assignee: MATSUSHITA ELECTRIC INDUSTRIAL CO., LTD., Osaka (JP)

(21) Appl. No.: 11/850,771

(22) Filed: Sep. 6, 2007

(30) Foreign Application Priority Data
Sep. 7, 2006 (JP) 2006-242459
Sep. 15, 2006 (JP) 2006-251064

(51) Int. Cl. H01L 27/146

(52) U.S. Cl. 250/208.1

(57) ABSTRACT

An image sensor comprises, a substrate, a plurality of photoelectric converters mounted on the substrate, for each of which a photoelectric conversion layer is formed of an organic compound layer and is sandwiched between an anode and a cathode so as to perform photoelectric conversion based on incident light, drive circuits for detecting output provided by a signal current generated by the photoelectric converters and for reading signal charges, and a wiring for electrically connecting the photoelectric converters and the drive circuits, wherein, for the plurality of the photoelectric converters that form one read pixels, the size of a photoelectric conversion area differs in accordance with a sensitivity of each of the plurality of photoelectric converters.

### BACKGROUND

1. Field of the Invention

The present invention relates to an image sensor that extracts, as electric signals, various types of information, such as an object shape and an image.

2. Description of the Related Art

A contact type linear sensor that requires only a rod lens as an optical system and can be easily made compact is employed as an image sensor for a facsimile machine or a scanner. This contact linear sensor has a sensor length equivalent to the original document, and is provided by arranging a plurality of CMOS (Complementary Metal-Oxide Semiconductor) sensor chips, or CCD (Charge-Coupled Device) sensor chips that are formed of single crystal silicon.

Further, a technique has been developed whereby photoelectric converters used for an image sensor can be formed by a very simple method employing an organic material (see, for example, JP-T-2002-502120).

However, the following problems are present for the conventional technique.

For the contact linear sensor that employs CMOS sensor chips or CCD sensor chips formed of a single crystal silicon, these chips must be arranged accurately, and information at the joint portion where the chips are connected can not be exactly scanned.

On the other hand, when photoelectric converters are formed using an organic material as in the described above organic semiconductor image sensor (JP-T-2002-502120), a photoelectric converter array having a predetermined size and a predetermined resolution can be obtained by a very simple method. However, the sensitivity characteristics of the individual colors are biased for the photoelectric converters formed of the organic material.

Furthermore, a drive circuit that detects and reads a signal charge from a photoelectric converter is generally formed of a silicon transistor. Since this manufacturing process is different from the process for the photoelectric converters, the drive circuit is located at a predetermined distance from the photoelectric converters. As a result, when the photoelectric converters are arranged on the same line for the individual colors, the pixel size and a distance from the drive circuit are different in accordance with the color, and this difference adversely affects the performance.

### SUMMARY

An image sensor according to this invention comprises:

a substrate;

a plurality of photoelectric converters, mounted on the substrate, for each of which a photoelectric conversion layer is formed of an organic compound layer and is sandwiched between an anode and a cathode so as to perform photoelectric conversion based on incident light;

drive circuits for detecting output provided by a signal current generated by the photoelectric converters, and for reading signal charges; and

wiring for electrically connecting the photoelectric converters and the drive circuits,

wherein, for the plurality of the photoelectric converters that form one read pixels, the size of a photoelectric conversion area differs in accordance with a sensitivity of each of the plurality of photoelectric converters.

With this arrangement, a signal transmitted by each photoelectric converter can be accurately detected at the high SN ratio, and the variance between the sensitivity characteristics of the photoelectric converters of the individual colors can be adjusted using the difference of the pixel size. As a result, a signal from the photoelectric converter of each color can be detected in a short period of time.

### BRIEF DESCRIPTION OF THE DRAWINGS

FIG. 1 is a perspective view of the external appearance of an image reading apparatus according to a first embodiment of the present invention.

FIG. 2 is a schematic cross sectional view of the internal structure of the image reading apparatus for the first embodiment.

FIG. 3 is a diagram showing the structure of the photoelectric conversion unit for the first embodiment.

FIG. 4 is an explanatory diagram for the image sensor for the first embodiment.

FIG. 5 is a diagram showing the arrangement relationship between the photoelectric converters and the drive circuits of the image sensor for the first embodiment.

FIG. 6 is a diagram showing the structure of the photoelectric converter according to the first embodiment.

FIG. 7 is a circuit diagram showing the structure of one pixel of the image sensor according to the first embodiment.

FIG. 8 is a diagram illustrating the arrangement of the photoelectric converters and the drive circuits of an image sensor according to a second embodiment.

FIG. 9 is a schematic top view illustrating an example of the photoelectric conversion device according to the invention.

FIG. 10 is a schematic diagram of the section taken along line IV-IV illustrated in FIG. 9.

FIG. 11 is a schematic diagram illustrating a planar arrangement of anodes used for organic photoelectric conversion elements in the area A shown in FIG. 9.

FIG. 12 is a schematic diagram illustrating a planar arrangement of pads in the area B shown in FIG. 9.

FIG. 13 is a schematic cross-sectional view illustrating position relation between the anode used for the organic photoelectric conversion element and the insulation layer in the photoelectric conversion section illustrated in FIG. 9.

FIG. 14 is a schematic cross-sectional view illustrating position relation between the anode used for the organic photoelectric conversion element and the insulation layer in the photoelectric conversion section illustrated in FIG. 9.

FIG. 15 is a schematic cross-sectional view illustrating surface position relation among the read-out wires, the pads to which the read-out wires are connected, and insulation layer.

FIG. 16 is a schematic cross-sectional view illustrating an optical filter section and a passivation layer formed on a single side of a transparent substrate in a manufacturing process of a photoelectric conversion substrate by a manufacturing method of the photoelectric conversion device according to the invention.

FIG. 17 is a schematic cross-sectional view illustrating the anode used for the organic photoelectric conversion element, the read-out wire, and a second wire formed in the manufacturing process of the photoelectric conversion substrate by the manufacturing method of the photoelectric conversion device according to the invention.

FIG. 18 is a schematic cross-sectional view illustrating the pads formed in the manufacturing process of the photoelectric conversion substrate by the manufacturing method of the photoelectric conversion device according to the invention.

FIG. 19 is a schematic cross-sectional view illustrating a basis insulation layer of the insulation layer formed in the manufacturing process of the photoelectric conversion substrate by the manufacturing method of the photoelectric conversion device according to the invention.

FIG. 20 is a schematic cross-sectional view illustrating an organic photoelectric conversion layer, a cathode, and a sealing section formed in the manufacturing process of the photoelectric conversion substrate by the manufacturing method of the photoelectric conversion device according to the invention.

FIG. 21 is a schematic cross-sectional view illustrating a read-out circuit section mounted on the photoelectric conversion substrate in a mounting process by the manufacturing method of the photoelectric conversion device according to the invention.

### DETAILED DESCRIPTION

The preferred embodiments of the present invention will now be described. These embodiments can be employed within the range relevant to each other.

### Embodiment 1

An Image Sensor According to this Embodiment, a Photoelectric conversion unit, or an image reading apparatus employing these is applied to an apparatus, such as a facsimile machine or a scanner, that converts the image of an object, such as an original document, into an electric signal, and obtains image data.

The image reading apparatus moves a photoelectric conversion unit, which includes an image sensor, relative to the original document, displaces the image pickup position of the original document, and creates image data based on the electric signal output by the photoelectric conversion unit. It should be noted that the image reading apparatus may be either a reflection type or a transmission type.

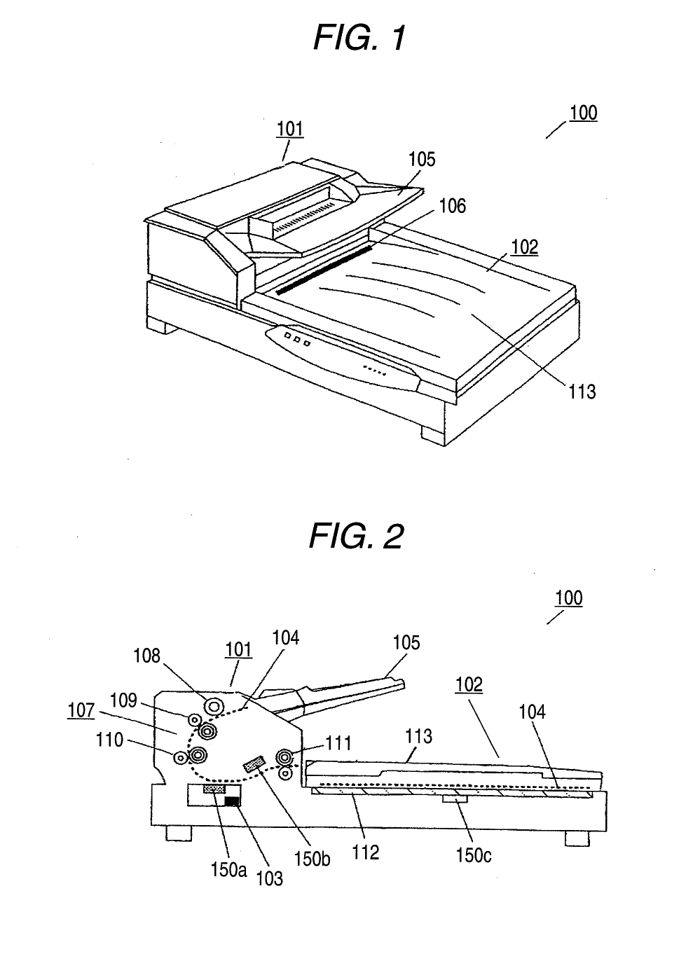

FIG. 1 is a perspective view of the external appearance of an image reading apparatus according to a first embodiment of the present invention. FIG. 2 is a schematic cross sectional view of the internal structure of the image reading apparatus for the first embodiment. A scanner is shown as an example for the image reading apparatus.

Referring to FIGS. 1 and 2, an image reading apparatus 100 employs image sensors 150a, 150b and 150c to read information for an original document 104 at two locations, i.e., an automatic document feeder 101 and a flatbed unit 102.

Two photoelectric conversion units 150a and 150b are arranged in the automatic document feeder 101, and a photoelectric conversion unit 150c is arranged in the flatbed unit 102.

The automatic document feeder 101 internally includes: a document feeding section 107 formed of a guide roller 108 and guide rollers 109, 110 and 111, each provided as a pair. The original document 104 mounted on a supply table 105 is guided by the guide roller 108 to the guide rollers 109, and thereafter to the guide rollers 110 and the guide rollers 111, and is discharged through a discharge port 106 to the flatbed unit 102.

The two photoelectric conversion units 150a and 150b are located between the guide rollers 110 and the guide rollers 111. The photoelectric conversion unit 150a performs image-pickup of the original document 104 from below, and converts the obtained image into an electric signal. The photoelectric conversion unit 150b performs image-pickup of the original document 104 from above, and converts the obtained image into an electric signal. As a result, information on the double sides of the original document 104 can be scanned by only conveying the original document 104 one time.

On the other hand, the flatbed unit 102 includes an document table 112 made of a transparent material, such as glass, and a document cover 113 that covers the document table 112 to block light. Since the photoelectric conversion unit 150c is located under the document table 112, the photoelectric conversion unit 150c is moved horizontally by moving means (not shown), performs image-pickup of the original document 104 from below, and converts the obtained image into an electric signal.

An image data preparation unit 103 is connected to the photoelectric conversion units 150a, 150c and 150c, and employs the electric signals prepared by the individual photoelectric conversion units 150a, 150b and 150c to create image data consonant with the electric signals.

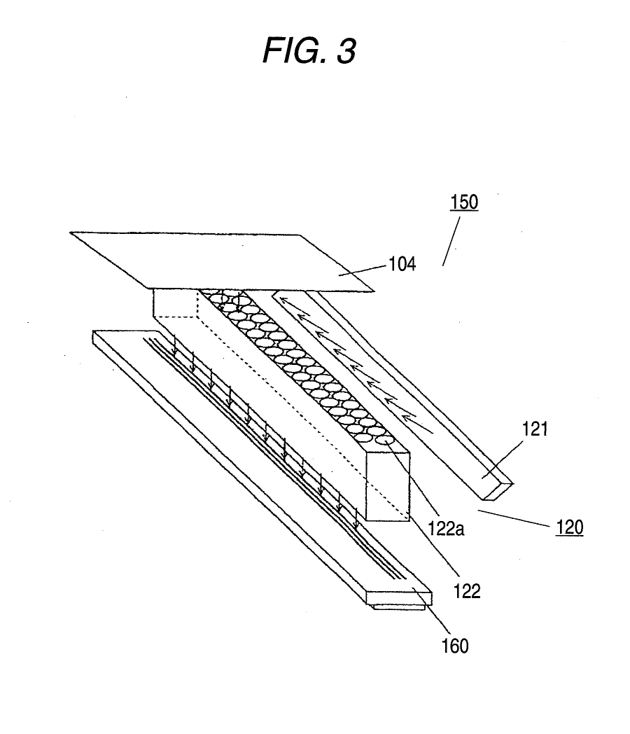

FIG. 3 is a diagram showing the structure of the photoelectric conversion unit for the first embodiment, i.e., the photoelectric conversion unit 150 (150a, 150b or 150c). It should be noted that an example for a reflection type is shown in FIG. 3.

In FIG. 3, the photoelectric conversion unit 150 includes an image sensor 160 and an image pickup optical system 120. The image pickup optical unit 120 forms the image of the original document 104, and the image sensor 160 converts this image into an electric signal.

The image pickup optical system 120 includes an artificial light source 121, and an optical system 122 that forms an image using light that is emitted by the artificial light source 121 and is reflected on the original document 104. The artificial light source 121 is, for example, a linear light source where predetermined numbers of red light emitting diodes, green light emitting diodes and blue light emitting diodes are arranged, or a white fluorescent lamp, and emits light obliquely upward.

Further, the optical system 122 is, for example, a rod lens array having multiple rod lenses 122a. The optical system 122 guides, vertically downward, light that is emitted by the artificial light source 121 and reflected on the original document 104, and forms an image vertically below the optical system 122.

The image sensor 160 internally receives light that is entered from the optical system 122, and converts the light into an electric signal.

It should be noted that the artificial light source 121, the optical system 122 and the image sensor 160 are supported by a single holding member (not shown), and are maintained at the positions shown in FIG. 3.

The image of the original document 104 formed by the image pickup optical system 120 is converted into an electric signal by the image sensor 160.

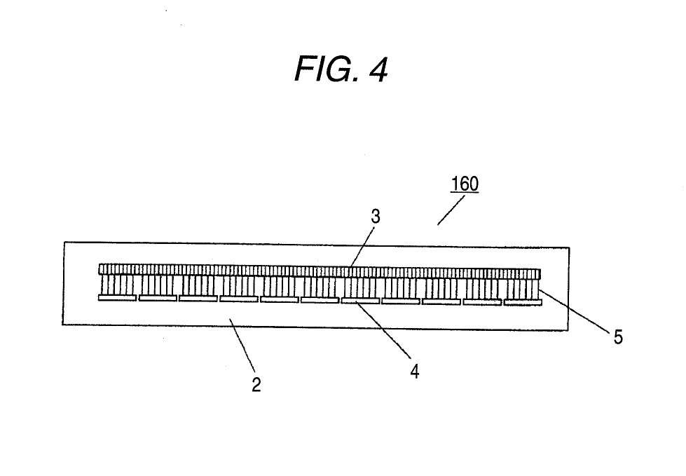

FIG. 4 is an explanatory diagram for the image sensor 160 for the first embodiment, i.e., a plan view of a glass substrate 2 used for the image sensor 160.

In FIG. 4, the glass plate 2 serves as a substrate for the image sensor 160 in the first embodiment, and photoelectric converters 3 for the image sensor 160 are formed of an organic material. Drive circuits made of a single crystal silicon are mounted on IC (Integrated Circuit) chips 4, and wiring 5 is used to connect the individual photoelectric converters 3 and the IC chips 4.

Although not shown, the IC chips 4 each include a detector, for detecting signal charges generated by the photoelectric converters 3; and a signal load reader, for reading the signal charge detected by the detector.

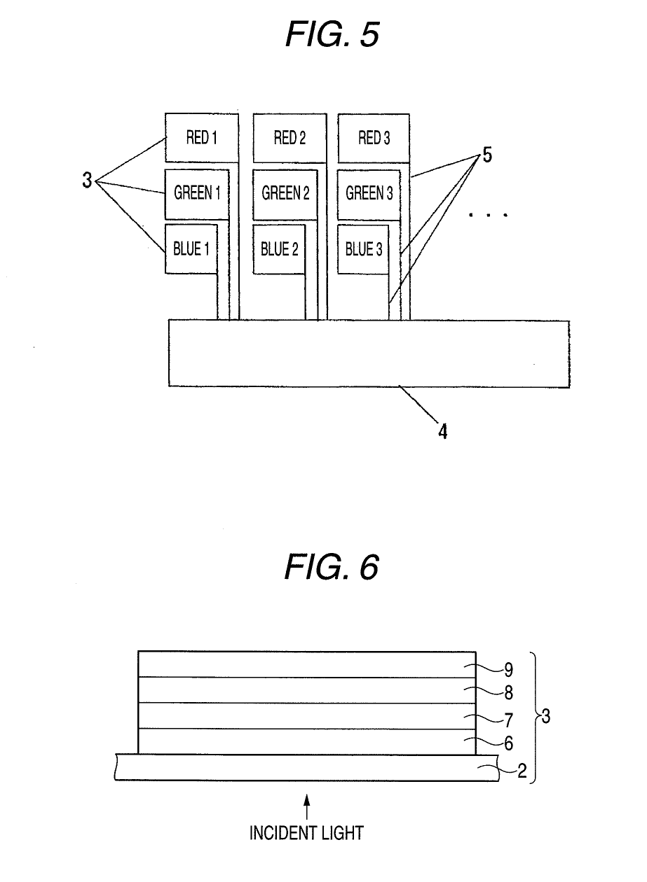

FIG. 5 is a diagram showing the arrangement relationship between the photoelectric converters 3 and the drive circuits of the image sensor 160 for the first embodiment.

The image sensor 160 in this embodiment is an image sensor that reads a color image. As shown in FIG. 5, for the photoelectric converters 3, red 1, red 2, red 3, . . . , green 1, green 2, green 3, . . . , or blue 1, blue 2, blue 3, . . . indicate that photoelectric conversion of red light, green light or blue light is performed, and for example, red 1, green 1 and blue 1 consist of one scan pixel.

According to the arrangement shown in FIG. 5, red 1, green 1 and blue 1 that consist of one scan pixel are arranged perpendicular to the direction in which the input terminals (not shown) of the IC chip 4 are arranged.

Especially, the photoelectric converters 3 are arranged so that, for each color, the distance between the photoelectric converter 3 and the input terminal (not shown) of the drive circuit of the IC chip 4 is changed.

According to the example shown in FIG. 5, the distance between the photoelectric converters 3 (red 1, red 2, red 3, . . . ) that perform photoelectric conversion of red light and the input terminals of the drive circuit of the IC chip 4 is the longest, and the distance between the photoelectric converters 3 (blue 1, blue 2, blue 3, . . . ) that performs photoelectric conversion of blue light and the input terminals of the drive circuit of the IC chip 4 is the shortest. Therefore, the photoelectric conversion areas for the photoelectric converters 3 that perform photoelectric conversion of blue light are reduced, because of the position of the wiring 5 that connects the red and green photoelectric converters 3 and to the IC chip 4.

On the other hand, the photoelectric converters 3 that perform photoelectric conversion of red light are not affected by the wiring 5 that connects the green and blue photoelectric converters 3 to the IC chip 4, a large size (light receiving area) can be obtained for the photoelectric converters 3. This arrangement is employed because (expression 1) is established for the relationship of the product of the maximum illuminances I_{R}, I_{G} and I_{B} and sensitivities α_{R}, α_{G} and α_{S} of the individual colors wherein I denotes the maximum incident illuminance for the photoelectric converter 3, a denotes the sensitivity, and subscripts R, G and B denote the colors of light, for which the red, green and blue photoelectric converters 3 perform photoelectric conversion.

I_{R}×α_{R}≦I_{G}×α_{G}≦I_{B}×α_{B} (Expression 1)

When a small photoelectric conversion area is prepared for a high sensitivity, and a large photoelectric conversion area is prepared for a low sensitivity, the variance of the sensitivity characteristics of the photoelectric converters 3 formed of an organic material can be reduced.

Furthermore, when the maximum illuminances I_{R}, I_{G} and I_{B} of the individual colors are constant, (expression 1) also means that, as the sensitivity α_{R}, α_{G}, or α_{B} is low, the pertinent photoelectric converter 3 is arranged apart from the input terminal of the drive circuit of the IC chip 4, and as the sensitivity α_{R}, α_{G}, or α_{B} is high, the pertinent photoelectric converter 3 is arranged close to the input terminal of the drive circuit of the IC chip 4.

It should be noted that the sensitivity level is varied depending on an organic material to be employed for the photoelectric converters 3. However, since the sensitivity for red light is generally low, it is preferable that, even when the maximum illuminances I_{R}, I_{G} and I_{B} of the individual colors and the sensitivities α_{R}, α_{G} and α_{S} are not known, the photoelectric converters 3 (red 1, red 2, red 3, . . . ) that perform photoelectric conversion for red light be arranged closest to the IC chip 4, as shown in FIG. 5.

The structure for the photoelectric converters 3 will now be described.

FIG. 6 is a diagram showing the structure of the photoelectric converter 3 according to the first embodiment, i.e., showing the cross sectional image of the photoelectric converter 3.

In FIG. 6, a color filter 6 of the photoelectric converter 3 is formed on the glass substrate 2, an ITO (Indium Tin Oxide) anode 7 serves as a first electrode for the photoelectric converter 3, an organic photoelectric conversion layer 8 of the photoelectric converter 3 is formed of an electron donating layer made of an electron donating material and an electron accepting material made of an electron accepting material, and an aluminum cathode 9 serves as a second electrode for the photoelectric converter 3.

As shown in FIG. 6, the photoelectric converter 3 has a structure wherein the color filter 6, the ITO anode 7, the organic photoelectric conversion layer 8 and the aluminum cathode 9 are laminated in order on the glass substrate 2.

On the glass substrate 2, the ITO anode 7 and the IC chip 4 are electrically connected together via the wiring 5, and an electric signal that the photoelectric converter 3 has obtained through photoelectric conversion for incident light is transmitted to the IC chip 4 via the wiring 5.

The method for manufacturing the above described image sensor 160 will now be described.

First, a pigment resist where a pigment is dispersed is coated on the glass substrate 2, and the glass substrate 2 is prebaked. Then, the glass substrate 2 is exposed via a photomask, and is developed using an alkaline developing liquid to obtain a color pattern. This process is repeated by three times for the three primary colors of R (red), G (green) and B (blue), and R, G and B color filters 6 are formed for the individual rows.

Sequentially, by the sputtering method, an ITO film of 150 nm is deposited on the color filters 6 formed on the glass substrate 2, and a resist material (e.g., OFPR-800 made by Tokyo Ohka Kogyo Co., Ltd.) is applied on the ITO film by spin coating, so that a resist film of 5 μm is formed. Then, masking, exposing and developing are performed, and the resist is patterned into the shape for the ITO anode 7 and the wiring 5 (the shape shown in FIG. 5).

Thereafter, this glass substrate 2 is immersed in a hydrochloric acid solution of 18N at 60° C., and the portion of the ITO film where the resist film is not formed is etched. Then, the glass substrate 2 is rinsed with water, and finally, the resist film is removed to obtain the ITO anode 7 and the wiring 5 that are formed of the ITO film in a predetermined pattern shape. Through this process, as shown in FIG. 5, as the ITO anode 7 of the organic photoelectric conversion layer 7 is located apart from the IC chip 4, the size of the ITO anode 7 is increased. Further, as the ITO anode 7 is located close to the IC chip 4, the size of the ITO anode 7 is reduced because the arrangement position must be obtained for the wiring 5 that is connected to an ITO anode 7 arranged farther from the IC chip 4 than this small ITO anode 7. As described above, unlike for multi-layer wiring, only one process for film deposition, exposing and developing is required for the ITO anode 7 and the wiring 5, so that the reliable ITO anode 7 and the wiring 5 can be formed through a small number of process steps.

Following this, a cleaning process is performed for the glass substrate 2 in order of ultrasonic cleaning for five minutes using a detergent (e.g., Semicoclean made by Furuuchi Chemical Corporation), ultrasonic cleaning for ten minutes using pure water, ultrasonic cleaning for five minutes using a solution by mixing a hydrogen peroxide solution and water with ammonia water at volume ratio of 1:5, and ultrasonic cleaning for five minutes using pure water at 70° C. Then, water is removed from the glass substrate 2 using a nitrogen blower, and the resultant glass substrate 2 is dried by heating at 250° C.

Sequentially, poly (3,4) ethylene dioxythiophene/polystyrene sulfonate (PEDT/PSS) is dripped through a filter of 0.45 μm on the glass substrate 2 where the ITO anode 7 is formed, and is uniformly applied by spin coating. Then, the resultant glass substrate 2 is heated in a clean oven at 200° C. for ten minutes, so that a charge transportation layer of 60 nm (not shown) is formed.

Then, a chlorobenzene solution that contains, at a weight ratio of 1:4, poly (2-methoxy-5-(2′-ethylhexyloxy)-1,4-phenylenevinylene) (MEH-PPV), which functions as an electron donating organic material, and [5,6]-phenyl C61 butylic acid methyl ester ([5,6]-PCBM), which functions as an electron accepting material, is spin coated on the ITO anode 7. The resultant glass substrate 2 is heated in a clean oven at 100° C. for thirty minutes, and the organic photoelectric conversion layer 8 of about 100 nm is formed. In this case, any deposition method for the photoelectric conversion layer 8 can be employed so long as a homogeneous, very smooth, thin film can be stably formed. An appropriate vacuum process, such as the vacuum deposition method or the sputtering method, or a wet process, such as the spin coating, the dipping method or the inkjet method, can be appropriately employed. An arbitrary process can be selected in accordance with a material and a structure to be employed, and especially, it is preferable that the organic photoelectric conversion layer 8 be formed by performing the wet process that does not require a large manufacturing apparatus, because the superior productivity is obtained and the manufacturing cost is reduced.

Finally, in a resistance heating vapor deposition apparatus wherein the pressure is reduced to the vacuum level equal to or lower than 0.27 mPa (=2×10⁻⁶ Torr), LIF of about 1 nm, and then aluminum of about 10 nm are deposited on the organic photoelectric conversion layer 8, and an aluminum cathode 9 is formed. In this manner, the photoelectric converters 3 for the individual colors can be formed in consonance with the rows.

It should be noted that MEH-PPV is a p-type organic semiconductor, and [5,6]-PCBM is an n-type semiconductor, and that electrons of the exciton generated by light absorption are donated to [5,6]-PCBM through diffusion of the conduction band, and the holes are donated to MEH-PPV through the diffusion of the valence band. Thus, these are transmitted through the bands to the aluminum cathode 9 and the ITO anode 7, respectively.

This [5,6]-PCBM is a modified fullerene type, and has a very great electron mobility. Further, since the mixture with MEH-PPV that is an electron donating material can be employed, the separation and conveying of a pair of an electron and a hole can be effectively performed. Therefore, the photoelectric conversion efficiency is improved, and the manufacturing at a low cost can be performed.

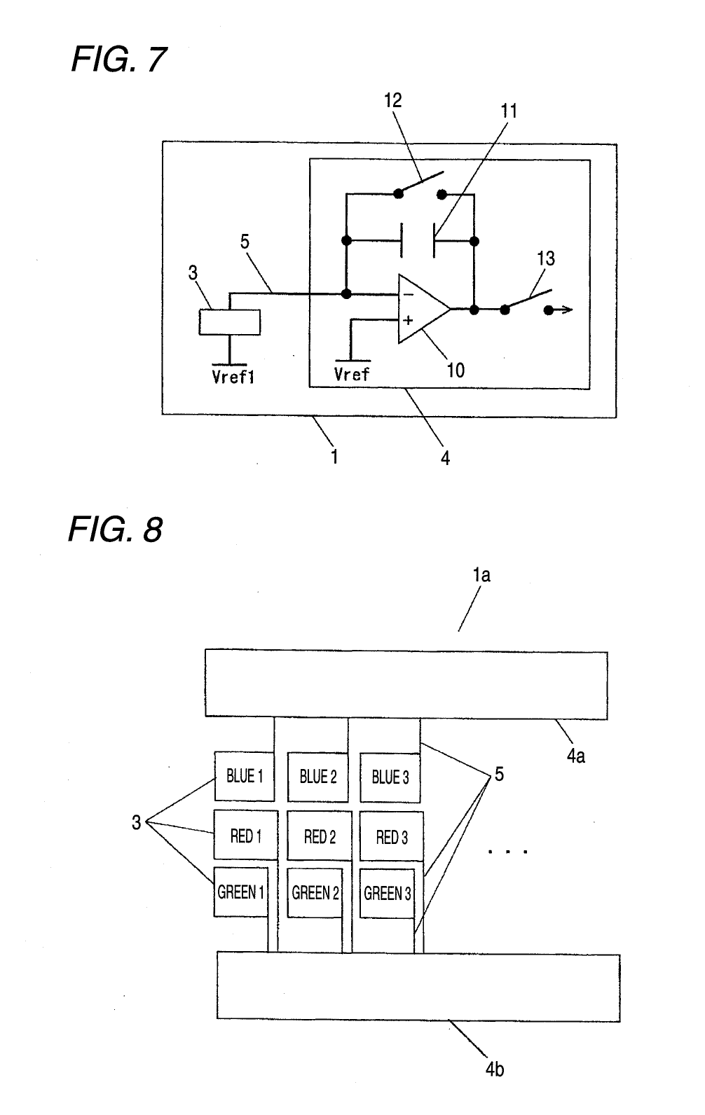

The operation of the thus arranged image sensor 160 will now be described while referring to FIG. 7.

FIG. 7 is a circuit diagram showing the structure of one pixel of the image sensor 160 according to the first embodiment.

In FIG. 7, this arrangement includes: an operating amplifier 10, a capacitor 11, a reset switch 12, for resetting charges accumulated in the capacitor 11; and a read switch 13 to read a voltage value that is stored. The capacitor 11 is located between the inversion input terminal and the output terminal of the operating amplifier 10 so as to constitute an integrated circuit. Further, the operating amplifier 10 is so connected that the potential of the aluminum cathode 9 of the photoelectric converter 3 is Vref1 level, and the potential of the non-inversion input terminal of the operating amplifier 10 is Vref level (Vref1>Vref in this case). Furthermore, the ITO anode 7 of the photoelectric converter 3 is connected to the inversion input terminal of the operating amplifier 10 via the wiring 5.

It should be noted that only detection means of the drive circuit of the IC chip 4 is shown in FIG. 7. Since the conventionally known circuit can be employed for the portion of the signal charge reading means, this circuit is not shown.

In FIG. 7, first, the reset switch 12 is turned on to reset the capacitor 11. At this time, the output voltage of the operating amplifier 10 is Vref level.

Then, the reset switch 12 is turned off. At this time, when light enters the photoelectric converter 3 formed of an organic material, the light is converted into a photocurrent, and this photocurrent is transmitted via the ITO anode 7 and the wiring 5 to the IC chip 4 where the drive circuit is mounted. In the IC chip 4, the operating amplifier 10 performs the feedback via the capacitor 11, so that a potential difference at the two input terminals becomes 0, and the photocurrent is accumulated in the capacitor 11. Therefore, the output level of the operating amplifier 10 is changed from the Vref level in accordance with the amount of the photocurrent that is supplied, the capacitance of the capacitor 11 and the accumulation period.

When predetermined time has been reached, the read switch 13 is controlled, and the output of the operating amplifier 10 is sequentially read by the signal charge detection means of the IC chip 4. The timings to perform these operations are controlled by a shift register (not shown).

When the resetting, the storing and the reading operations described above are repeated, information for the individual pixels (the individual colors inside the pixels) can be obtained. According to this method, since the lines of the wiring 5 along which the photocurrent flows are constantly maintained at the Vref by the operating amplifier 10, the output potential of the operating amplifier 10 is not affected even when the capacitance is increased in consonance with the wiring 5.

Thus, when the capacitance of the capacitor 11 and the accumulation period are constant, the change of the output potential of the operating amplifier 10 is determined in accordance with the amount of a photocurrent. For the photoelectric converter 3 that has the small product of the maximum illuminance I and the sensitivity α, since, originally, a small amount of photocurrent flows after the photoelectric conversion has been performed, this photoelectric converter 3 is located apart from the input terminal of the drive circuit of the IC chip 4 to avoid the affect of the arrangement of the wiring 5. Therefore, a large photoelectric conversion area is obtained, and thus, the change of the output potential can be increased. And with this arrangement, since the change due to signal charge can be obtained although the accumulation period is short, it is useful for the fast processing.

According to the first embodiment, for connection to the photoelectric converter 3, the mounting method is employed whereby chips are manufactured by forming, on a single crystal substrate, a circuit that detects the photocurrent of the pixel, and a metal bump is attached to the bare chip IC, so that the chip IC can be bonded directly to the glass substrate 2 without performing wire bonding.

As described above, the photoelectric converter, for which only a small amount of photocurrent is generated through photoelectric conversion is located apart from the input terminal of the drive circuit. Therefore, the reduction of the change of the photoelectric converter 3 that is less changed can be controlled, and the signal charge can be detected at the high SN ratio (Signal to Noise ratio) for the whole color image sensor 160.

In the first embodiment, the present invention has been applied for a linear sensor. However, the present invention is not limited to a linear sensor, and can also be applied for an area sensor. In this case, for signal reading, an X-Y address type using two switching transistors need be employed.

Further, in the first embodiment, the glass substrate 2 has been employed. However, so long as the first electrode (the ITO anode 7), the organic photoelectric conversion layer 8 and the second electrode (the aluminum cathode 9) can be supported, any substrate may be employed. Other than the glass substrate 2, various macromolecular materials, such as polyethylene terephthalate, polycarbonate, polymethyl methacrylate, polyether sulfone, polyvinyl fluoride, polypropylene, polyethylene, polyacrylate, amorphous polyolefin and fluorocarbon, or various metal materials, such as polycon wafer, can be employed.

Furthermore, an example wherein, as shown in FIG. 6, the light transmission property is provided for the glass substrate 2 and the ITO anode 7, and light enters from the opposite side of the photoelectric converter 3 of the glass substrate 2 has been employed. However, the structure wherein a different material for the aluminum cathode 9 is used and light enters from the cathode side may be employed.

In addition, the electron donating material to form the organic photoelectric conversion layer 8 can be a copolymer of a monomer and a polymer that contains, as a repeating unit, phenylene vinylene and its derivative, or fluorene and its derivative, especially, fluorene copolymer (P0F66, P1F66 or PFPV) that has a quinoline group or a pyridine group in the framework, fluorene containing arylamine polymer, carbazole and its derivative, indole and its derivative, pyren and its derivative, pyrrole and its derivative, picoline and its derivative, thiophene and its derivative, acetylene and its derivative, or diacetylene and its derivative, or can be a group of macromolecular materials generally called a dendrimer.

Further, other than a macromolecular material, the following materials can also be employed; a polyphyrin compound, such as porphine, tetraphenylporphine copper, phthalocyanine, copper phthalocyanine or titanium phthalocyanine oxide; aromatic tertiary amine, such as 1,1-bis{4-(di-P-tolylamino)phenyl}cyclohexane, 4,4′,4″-trimethyltriphenylamine, N,N,N′,N′-tetrakis(P-tolyl)-P-phenylenediamine, 1-(N,N-di-P-tolylamino)naphthalene, 4,4′-bis(dimethylamino)-2-2′-dimethyltriphenylmethane, N,N, N′,N′-tetraphenyl-4,4′-diaminobiphenyl, N,N′-diphenyl-N,N′-di-m-tolyl-4,4′-diaminobiphenyl, N-phenylcarbazole; a stilbene compound, such as 4-di-P-tolylaminostilbene, 4-(di-P-tolylamino)-4′-[4-(di-P-tolylamino)stylyl]stilbene; triazole and its derivative; oxadiazole and its derivative; imidazole and its derivative; polyarylalkan and its derivative; pyrazoline and its derivative; pyrazolone and its derivative; phenylenediamine and its derivative; anylamine and its derivative; amino-substitution chalcone and its derivative; oxazole and its derivative; stylylanthracene and its derivative; fluorenon and its derivative; hydrazone and its derivative; silazane and its derivative; polysilane aniline type copolymer; macromolecular oligomer; a stylyl amine compound; an aromatic dimethylidyne compound; and poly-3-methylthiophene.

Furthermore, the electron accepting material for forming the organic photoelectric conversion layer 8 can be oxadiazole and its derivative, such as 1,3-bis(4-tart-butylphenyl-1,3,4-oxadiazoryl)phenylene (OXD-7), anthraquinodimethan and its derivative, diphenylchinone and its derivative, or fullerene and its derivative, especially, a PCBM ([6,6]-phenyl C61 butyric acid methyl ester) carbon nanotube and its derivative.

Instead of the ITO employed for the first embodiment, a transparent electrode made of ATO (SnO₂ where Sb is doped) or AZO (ZnO where Al is doped) can be employed as the first electrode (the anode) provided under the organic photoelectric conversion layer 8. Further, when the first electrode is made of a light transmission material, such as a thin metal film of Al, Ag or Au, the light transmission property can also be provided. Thus, the light receiving portion having the light transmission property can also be obtained.

Moreover, instead of Al for the first embodiment, a thin film made of metal, such as Ag, Au, Cr, Cu, In, Mg, Ni, Si or Ti, an Mg alloy, such as an Mg—Ag alloy or an Mg—In alloy, or an Al alloy, such as an Al—Li alloy, an Al—Sr alloy or an Al—Ba alloy, can also be employed to form the second electrode (the cathode) on the organic photoelectric conversion layer 8. In addition, in order to resolve the occurrence of a short-circuiting current, a method for depositing a metal oxide or a metal fluoride like LiF between the organic photoelectric conversion layer 8 and the second electrode is also properly employed. Further, ITO, ATO or AZO can also be employed as the second electrode (the cathode).

Furthermore, it is possible to employ, as needed, a device arrangement wherein a macromolecular material, such as PEDOT:PSS (a mixture of a polythiophene and a polystyrene sulfonic acid) is deposited as a buffer layer between the first electrode (the anode) or the second electrode (the cathode) and the organic photoelectric conversion layer 8, or a device arrangement wherein an inorganic material, such as silicon, titanic, alumina, carbon or zirconia, is inserted as a block layer for a leaking current.

In the first embodiment, the color filters 6 have been employed as means for separating the individual colors. However, instead of using the color filters 6, the spectral characteristics of the organic material may be employed.

According to the first embodiment, of the photosensitive converters 3 of the individual colors, a photoelectric converter 3 that has a smaller product of the maximum incident illuminance I (lux) and the sensitivity α[volt/(lux-time)] is located more at a distance from the input terminal of the drive circuit. Therefore, a photoelectric conversion area can be increased for the photoelectric converter 3 of the color for which the sensitivity is low. As a result, since the change of a predetermined signal current can be obtained, the signal charges generated from the photoelectric converters 3 of the individual colors can be accurately detected in high S/N ratio.

Further, since the photoelectric conversion area is increased for the color for which the sensitivity is low, and the photoelectric conversion area is reduced for the color for which the sensitivity is high, the variance of the sensitivities of the individual photoelectric converters 3 can be reduced using the difference of the sizes of the photoelectric conversion areas. As a result, the signal charges from the photoelectric converters 3 of the individual colors can be detected in a short period of time.

Further, since the drive circuits are constituted by the transistors formed of a single crystal silicon, the electron mobility is high, the fast operation is enabled, and the variance of the threshold value can be reduced. As a result, the image sensor 160 having the uniform sensitivity characteristic can be obtained.

### Embodiment 2

FIG. 8 is a diagram illustrating the arrangement of the photoelectric converters and the drive circuits of an image sensor according to a second embodiment of the present invention.

In FIG. 8, a drive circuit 4a drives photoelectric converters 3 that perform photoelectric conversion of blue light, and a drive circuit 4b drives photoelectric converters 3 that perform photoelectric conversion of green light and red light. Since the other structure is basically the same as that shown in FIG. 2 for the first embodiment, no further explanation will be given.

A difference of an image sensor 160a in the second embodiment from that in the first embodiment is that the drive circuits 4a and 4b are collectively formed on a glass substrate 2 using thin film transistors formed of polycrystal silicon or amorphous silicon.

According to this arrangement, unlike in the first embodiment, the IC chips 4, on which the drive circuits 4a and 4b formed of single crystal silicon are mounted, need not be attached in the bare state. Thus, the reliable color image sensor 1a can be produced at a lower cost.

Furthermore, since the drive circuits 4a and 4b can be located on both sides so as to sandwich the photoelectric converters 3, the photoelectric converters 3 for a color consonant with the greatest product of the maximum illuminance I and the sensitivity a can be located in either the upper or lower end row (the position close to the drive circuit 4a or 4b), and the photoelectric converters 3 for a color consonant with the smallest product of the maximum illuminance I and the sensitivity a can be located in the center row (the position apart from the two drive circuits 4a and 4b).

According to the second embodiment, in addition to the effects in the first embodiment, thin film transistors made of polycrystal silicon or amorphous silicon are employed as the silicon transistors that constitute the drive circuits 4a and 4b. Therefore, the drive circuits need not be mounted as chips on the glass substrate 2, and the color image sensor 1a can be provided at a low cost with superior productivity.

Furthermore, when the drive circuits 4a and 4b are located on both sides so as to sandwich the photoelectric converters 3, wiring 5 of the photoelectric converters 3 can be extended to both sides. Thus, a wiring distance can be reduced to prevent the affect of external noise. Moreover, the signal charges can be detected at a high SN ratio and the accumulation period can be reduced.

### Embodiment 3

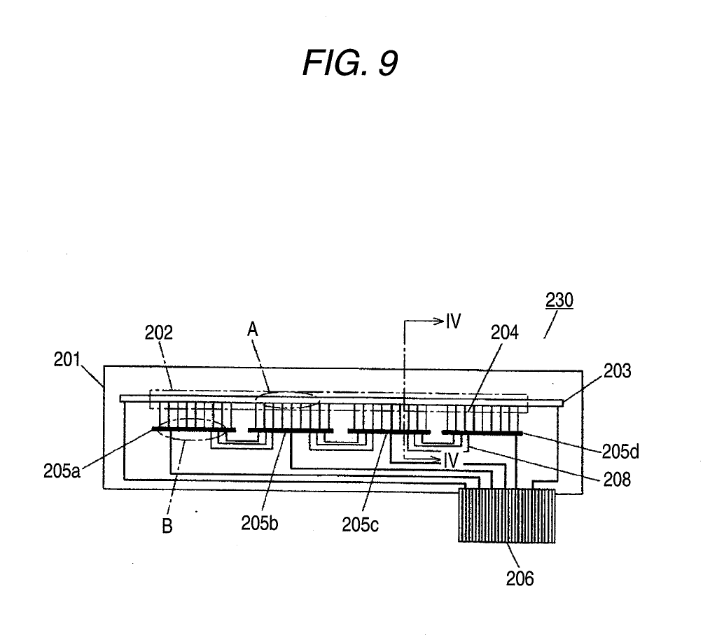

The photoelectric conversion device according to the invention includes a plurality of organic photoelectric conversion elements disposed on a substrate having a long plate shape and reads out signal electric charges for every group that is obtained by dividing the plurality of organic photoelectric conversion elements into a plurality of groups. Hereinafter, the photoelectric conversion device according to the invention will be described with reference to FIGS. 9 to 15.

FIG. 9 is a schematic top view illustrating an example of the photoelectric conversion device according to the invention. In reference numerals in the drawing, 201 is a transparent substrate, 202 is a photoelectric conversion section including the plurality of organic photoelectric conversion elements, 203 is a common cathode of organic photoelectric conversion elements, 204 is a read-out wire, 205a to 205d are read-out circuit sections, 206 is a circuit board, 207 is a first wire for connecting the read-out circuit section with the circuit board 206, 208 is a second wire for connecting the read-out circuit sections which neighbors with each other, and 230 is the photoelectric conversion device.

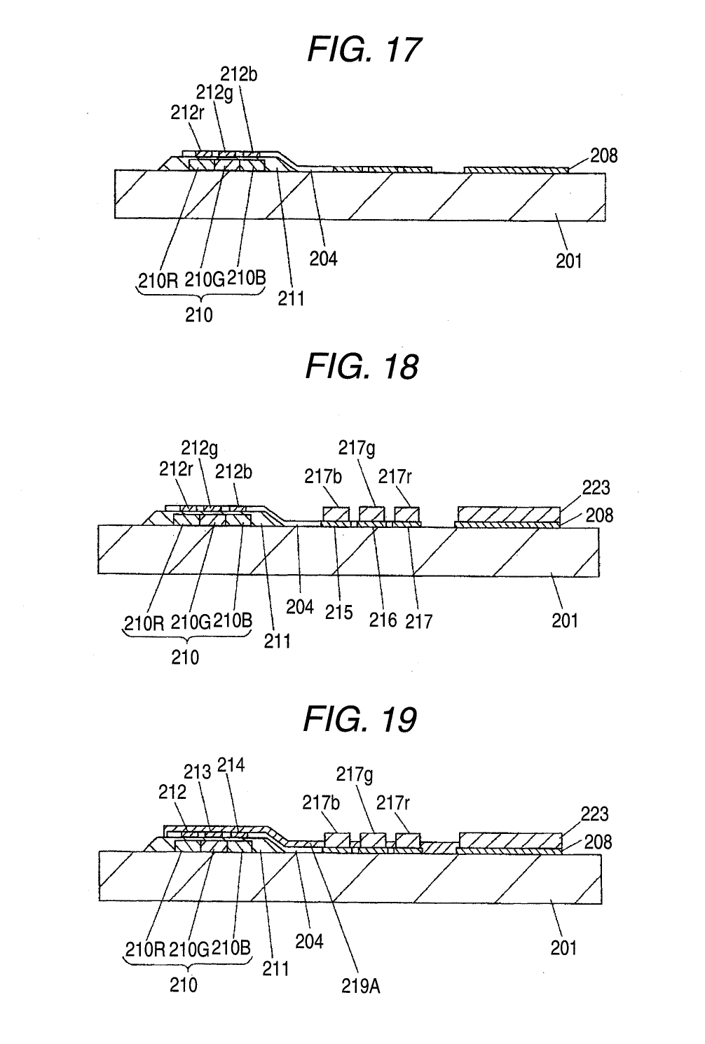

The photoelectric conversion device 230 illustrated in the drawing is used in a linear image sensor, and the photoelectric conversion device 230 includes the photoelectric conversion section 202 disposed on the transparent substrate 201 having a long plate shape and four read-out circuit sections 205a to 205d disposed on the outer side of the substrate. The photoelectric conversion section 202 includes the plurality of organic photoelectric conversion elements (not shown in FIG. 17) arranged in a longitudinal direction of the transparent substrate 201 and is shielded by a sealing section that is omitted in the drawing. Each organic photoelectric conversion element constituted of the photoelectric conversion section 202 is divided into a plurality of groups along the longitudinal direction of the transparent substrate 201 and is connected to predetermined read-out circuit sections 205a to 205d via the read-out wire 204 for every group. The read-out circuit sections 205a to 205d accompanied with the read-out wires 204 and pads to be described later forms a signal charge read-out means.

The read-out circuit sections 205a to 205d are semiconductor bare chips having a predetermined integrated circuit formed thereon. The read-out circuit sections 205a to 205d read out the signal electric charge via the read-out wire 204 from the organic photoelectric conversion elements corresponding thereto, respectively, and write a predetermined signal on the basis of the signal electric charge. The signal is sent to the circuit board 206 via a first wire 207. The predetermined semiconductor chip is mounted on the circuit board 206. The semiconductor chip writes image data by synthesizing the signals received from the read-out circuit sections 205a to 205d and supplies the synthesized signals to an outer circuit (not shown in the drawing) connected to the circuit board 206.

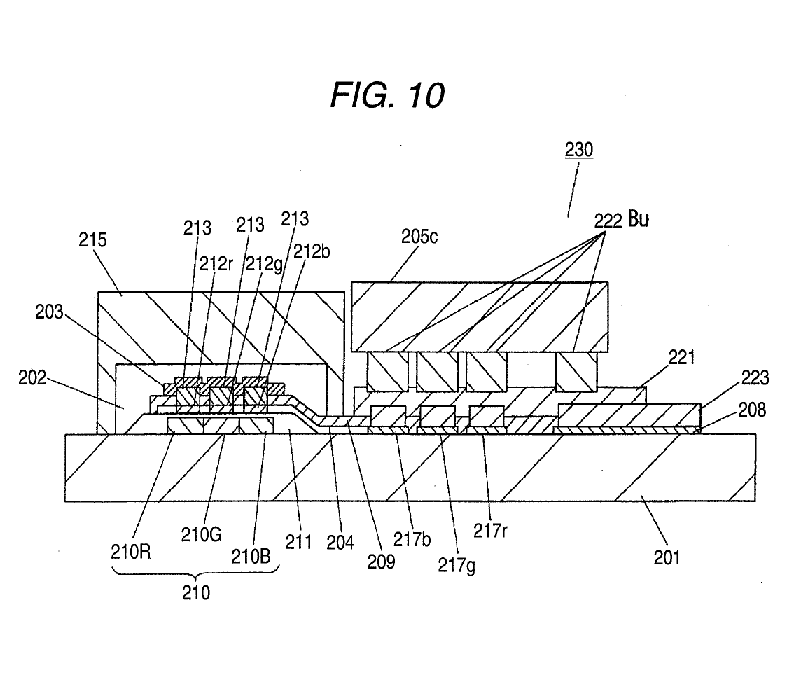

FIG. 10 is a schematic diagram of the section taken along line IV-IV illustrated in FIG. 9. As shown in the drawing, in the photoelectric conversion section 202, an optical filter section 210 constituted of a red filter 210R, a green filter 2106, and a blue filter 210B is disposed on the transparent substrate 201. Upon there, anodes 212r, 212g, and 212b used for organic photoelectric conversion element, the organic photoelectric conversion layer 213, and a cathode 203 used for organic photoelectric conversion element (hereinafter, it is refer to as ‘cathode 203’) are formed with a passivation layer 211 interposed therebetween.

An anode 212r used for organic photoelectric conversion element (hereinafter, it is refer to as ‘anode 212r’) is disposed on the red filter 210R. An anode 212g used for organic photoelectric conversion element (hereinafter, it is refer to as ‘anode 212g’) is disposed on the green filter 210G. An anode 212b used for organic photoelectric conversion element (hereinafter, it is refer to as ‘anode 212b’) is disposed on the blue filter 210B.

The anode 212r, 212g, or 212b is disposed on each photoelectric conversion element, one by one, and the organic photoelectric conversion layer 213 is formed so as to cover the anodes 212r, 212g, and 212b.

The cathode 203 is disposed so as to cover the organic photoelectric conversion layer 213. The cathode 203 is commonly used in all organic photoelectric conversion elements as described above and formed of one conductive layer. One organic photoelectric conversion element includes one anode 212r, 212g, or 212b, an area located on the anode 212r, 212g, or 212b in the organic photoelectric conversion layer 213, and an area located on the anode 212r, 212g, or 212b in the cathode 203. The organic photoelectric conversion elements are shielded by a sealing section 215 having a shallow box so as to cover all organic photoelectric conversion elements.

The read-out wire 204 corresponding to each organic photoelectric conversion element is formed so as to extend from an area on the passivation layer 211 to an area under the predetermined read-out circuit section 205a, 205b, 205c, or 205d. The end of the read-out wire 204 of the organic photoelectric conversion element side is connected to the predetermined anode 212r, 212g, or 212b. The end of the read-out wire 204 of the read-out circuit section side is formed with a large width, and a pad 217r, 217g, or 217b is formed on an area where the end has a large width. One pad 217r corresponds to one anode 212r, one pad 217g corresponds to one anode 212g, and one pad 217b corresponds to one anode 212b.

The insulation layer 219 prevents a cross-talk between the read-out wires 204 neighboring to each other and prevents mixing signal electric charges by electrically separating the read-out wires 204 from organic photoelectric conversion elements other than the organic photoelectric conversion elements to which the read-out wires 204 correspond, by covering up the read-out wires 204. The insulation layer 219 does not cover up the pads 217r, 217g, and 217b and contacts sides of the pads 217r, 217g, and 217b. When the insulation layer 219 is formed in this manner, even when the read-out circuit sections 205a to 205d is mounted on the transparent substrate 201 with an anisotropy conduction film 221, which will be described later, interposed therebetween, occurrence of conduction in an undesired location due to permeation of the conductive particles included in the anisotropy conduction film 221 into an area between the insulation layer 219 and the pad 217r, 217g, or 217b can be prevented. As a result, it becomes easy to obtain high quality image data when a linear image sensor is configured by using the photoelectric conversion device 230.

Each read-out circuit sections 205a to 205d (in FIG. 10, only the read-out circuit section 205c is shown) has a plurality of bumps Bu formed on a single side thereof and are formed by a flip chip bonding on the transparent substrate 201 with the anisotropy conduction film 221 interposed therebetween. Specifically, each read-out circuit sections 205a to 205d is mounted on the transparent substrate 201 by connecting the predetermined pad 217r, 217g, or 217b disposed on the transparent substrate 201 with the predetermined bump Bu through the anisotropy conduction film 221. Additionally, the anisotropy conduction film 221 covers up the pads 217r, 217g, and 217b and also covers up a part of an area of the insulation layer 219 near by the pads 217r, 217g, and 217b. A reference numeral ‘223’ in FIG. 10 represents a pad formed on one end of second wires 208 (see FIG. 9). The pad 223 is connected to the predetermined bump Bu in the read-out circuit section 205c via the anisotropy conduction film 221.

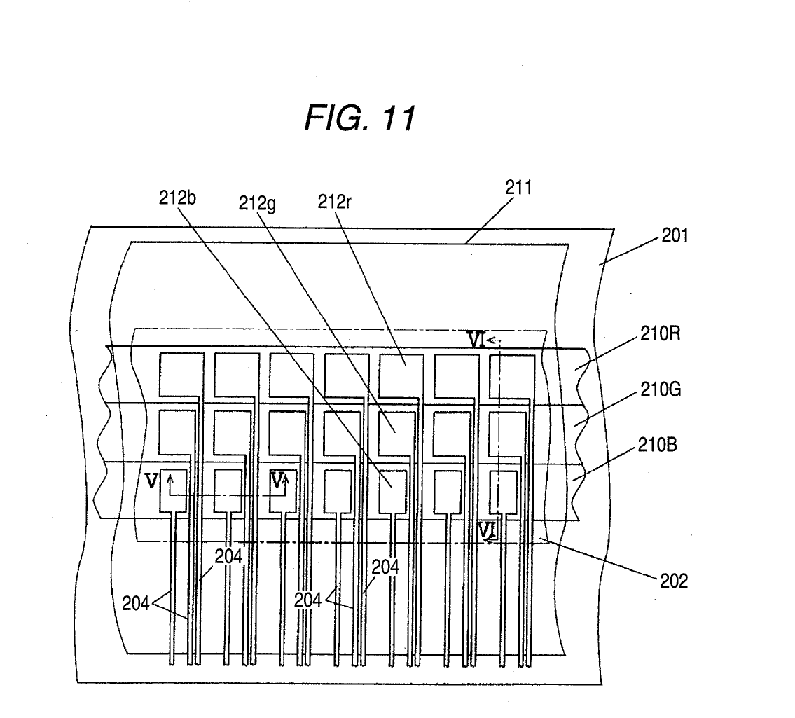

FIG. 11 is a schematic diagram illustrating a planar arrangement of the anodes 212r, 212g, and 212b in the photoelectric conversion section 202 and schematically shows the planar arrangement of the anodes 212r, 212g, and 212b in the area as shown in FIG. 9. In the component members shown in the drawing, the component members previously described with reference to FIG. 9 or FIG. 10 will be denoted by the same reference numeral as the reference numeral used in FIG. 9 or FIG. 10, and the description thereof will be omitted.

As shown in FIG. 11, in the photoelectric conversion section 202, the three anodes 212r, 212g, and 212b arranged in a direction orthogonal to the longitudinal direction of the transparent substrate 201 as viewed from the top are defined as a repetition unit. The plurality of repetition units is arranged in the longitudinal direction of the transparent substrate 201. A plane shape of the organic photoelectric conversion element is practically determined by a plane shape of the anode in the organic photoelectric conversion element corresponding thereto. Thus, when the anodes 212r, 212g, and 212b are arranged as shown in the drawing, the three organic photoelectric conversion elements arranged in the direction orthogonal to the longitudinal direction of the transparent substrate 201 as viewed from the top are defined as a repetition unit. The plurality of repetition units forms an arranged structure that is arranged in the longitudinal direction of the transparent substrate 201. In the example shown in the drawing, the anodes 212r, 212g, and 212b and the read-out wires 204 are formed by patterning one transparent conduction film.

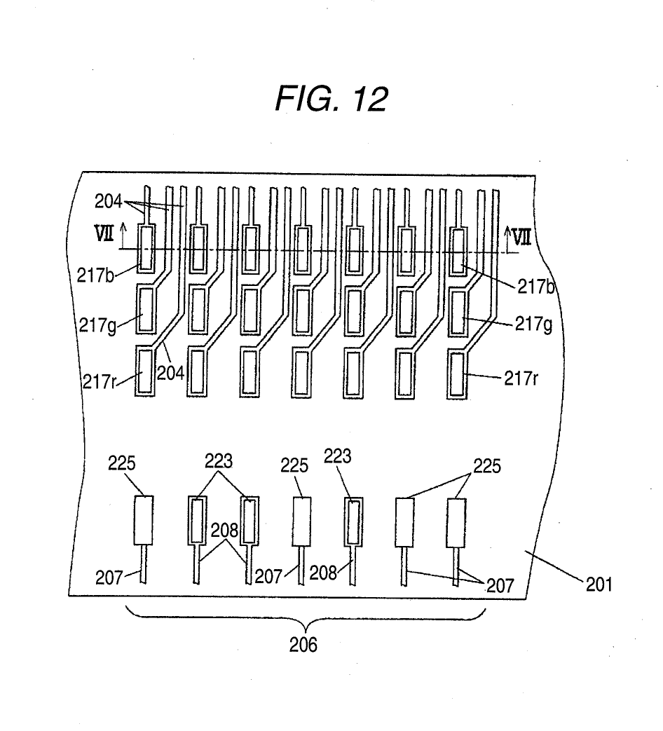

FIG. 12 is a schematic diagram illustrating a planar arrangement of the pads 217r, 217g, and 217b and schematically shows the planar arrangement of the pads 217r, 217g, and 217b in the area B shown in FIG. 9. In the component members shown in the drawing, the component members previously described with reference to FIG. 9 or FIG. 10 will be denoted by the same reference numeral as the reference numeral used in FIG. 1 or FIG. 2, and the description thereof will be omitted.

As shown in FIG. 12, the three pads 217r, 217g, and 217b corresponding to the three organic photoelectric conversion elements constituted of the aforementioned repetition unit is arranged in a direction orthogonal to the longitudinal direction of the transparent substrate 201 as viewed from the top.

The pads 217r corresponding to the anodes 212r (see FIG. 11), the pads 217g corresponding to the anodes 212g (see FIG. 11), and the pads 217b corresponding to the anodes 212b (see FIG. 11), all of them, are arranged in a single line in a longitudinal direction of the transparent substrate 201, respectively.

The two read-out wires 204 corresponding to the pads 217g and 217r are located between the two pads 217b and 217b neighboring to each other in the longitudinal direction. The one read-out wire 204 corresponding to the pad 217r is located between the two pads 217g and 217g neighboring to each other in the longitudinal direction. Any read-out wire 204 is not located between the two pads 217r and 217r neighboring to each other in the longitudinal direction. In addition, the reference numeral ‘225’ in the FIG. 12 represents a pad to which an end of the first wire 207 is connected.

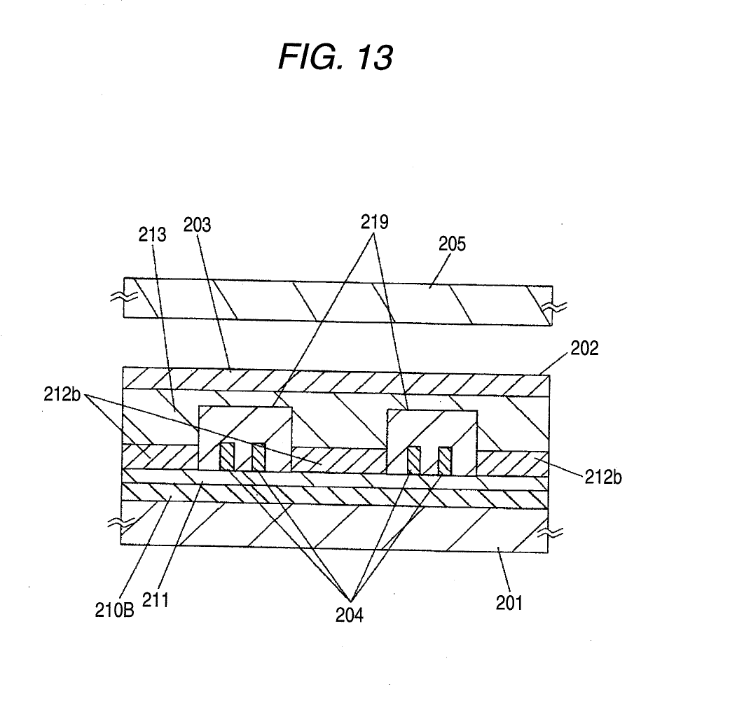

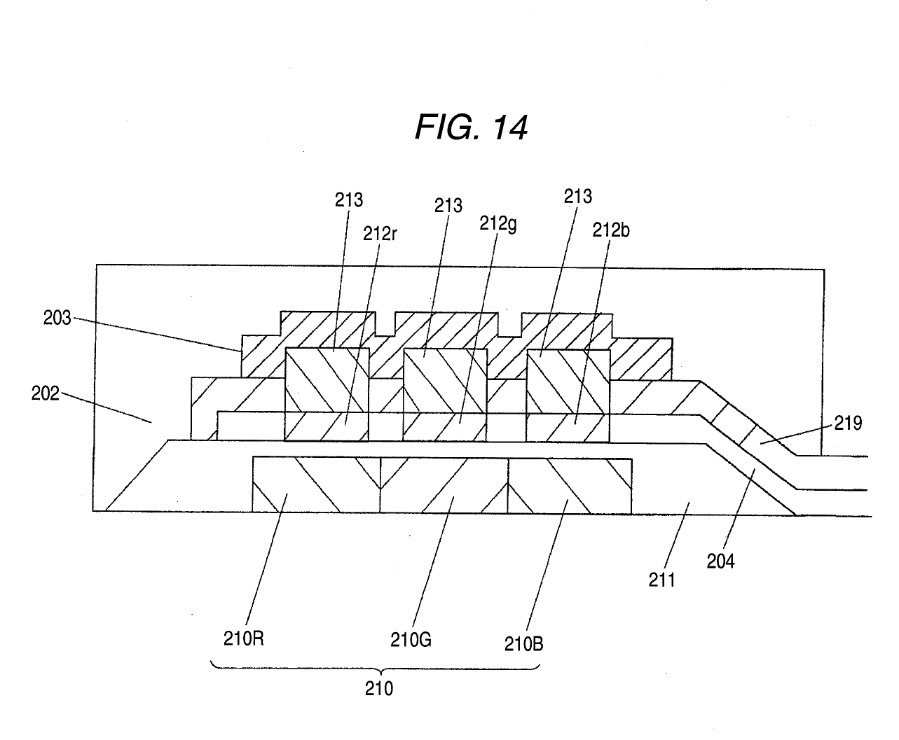

FIGS. 13 and 14 are schematic cross-sectional views illustrating position relation between the anode and the insulation layer in the photoelectric conversion section, respectively. FIG. 13 shows a section taken along the line V-V shown in FIG. 11, and FIG. 14 shows a section taken along the line IV-IV shown in FIG. 11. In the component members shown in these drawings, the component members previously described with reference to FIG. 9 or FIG. 10 will be denoted by the same reference numeral as the reference numeral used in FIG. 9 or FIG. 10, and the description thereof will be omitted.

In the photoelectric conversion section 202 as shown in FIG. 13 or 14, the anodes 212r, 212g, and 212b and the read-out wires 204 other than their connection portions are electrically separated by the insulation layer 219, and the read-out wires 204 neighboring to each other are electrically separated by the insulation layer 219. By disposing the insulation layer 219 in this manner. The insulation layer 219 prevents the read-out wires 204 from reading out signal electric charges from the organic photoelectric conversion elements (the organic photoelectric conversion layer 213) other than the organic photoelectric conversion elements (the organic photoelectric conversion layer 213) corresponding to the read-out wires 204, from mixing signal electric charges between the organic photoelectric conversion elements (the organic photoelectric conversion layer 213) neighboring to each other, and from causing a cross-talk between the read-out wires 204 neighboring to each other.

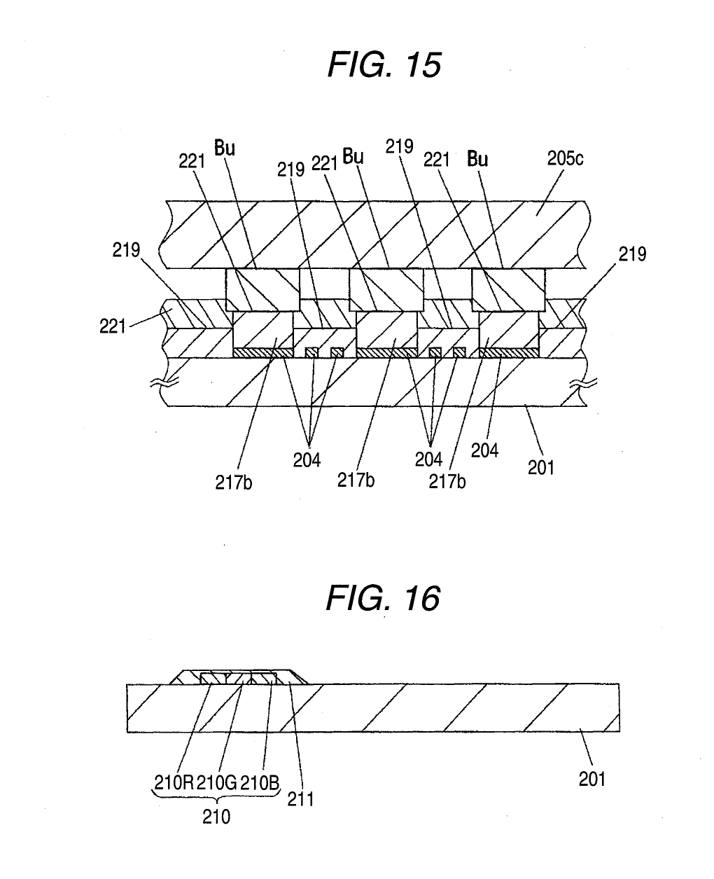

FIG. 15 is a schematic cross-sectional view illustrating surface position relation among the read-out wires, the pads to which the read-out wires are connected, and insulation layer. FIG. 15 shows a section taken along the line VII-VII shown in FIG. 12. In the component members shown in the drawing, the component members previously described with reference to FIG. 9 or FIG. 10 will be denoted by the same reference numeral as the reference numeral used in FIG. 9 or FIG. 10, and the description thereof will be omitted.

As shown in FIG. 15, when a surface position of the transparent substrate 201 is set by a reference position, each surface position of the pads 217r, 217g, and 217b is higher than a surface position of the insulation layer 219. Hence, when the read-out circuit sections 205a to 205d (in FIG. 15, the only read-out circuit section 205c is shown) are mounted on the transparent substrate 201 with the anisotropy conduction film 221 interposed therebetween, the read-out circuit sections 205a to 205d can be easily held down to desired height position without being disturbed by the insulation layer 219. As a result, it becomes easy to electrically connect the bump Bu with the pad 217r, 217g or 217b via the anisotropy conduction film 221.

The photoelectric conversion device 230 having the aforementioned structure is configured to dispose the organic photoelectric conversion elements on the transparent substrate 201, and thus it is easy to increase the length thereof. In addition, the signal electric charges are read by the signal charge read-out means (the read-out circuit sections 205a to 205d) from each organic photoelectric conversion element for every group, by dividing the organic photoelectric conversion elements disposed on the transparent substrate 201 into a plurality of groups. Therefore, even when the total number of the organic photoelectric conversion elements is large, the number of the organic photoelectric conversion elements in each group is minimized, and thus it is possible to read out the signal electric charges from all organic photoelectric conversion elements in a comparatively short time.

Accordingly, when a linear image sensor in which the longitudinal direction of the transparent substrate 201 in the photoelectric conversion device 230 is set by a scan direction is configured by employing the photoelectric conversion device 230, it becomes easy to obtain the linear image sensor having high resolution in the scan direction and a sub scan direction and high operation speed.

The photoelectric conversion device according to the invention that brings such a technical effect can be obtained by a manufacturing method of the photoelectric conversion device according to the invention to be described in, for example, Embodiment 4 as follows.

### Embodiment 4

A manufacturing method of photoelectric conversion device of the invention includes a manufacturing process and a mounting process of the photoelectric conversion substrate. Hereinafter, employing an example for obtaining the photoelectric conversion device 230 (see FIG. 9) described in Embodiment 3, the manufacturing method will be described for every process step of the invention with reference to the reference numeral used in FIG. 9 or 10.

### <Manufacturing Process of Photoelectric Conversion Substrate>

In the manufacturing process of the photoelectric conversion substrate, there is provided the photoelectric conversion substrate where the plurality of organic photoelectric conversion elements are arranged on the substrate having a long plate shape in the longitudinal direction of the substrate, the pads corresponding to the plurality of organic photoelectric conversion elements are arranged, respectively, and the read-out wires that connects the plurality of organic photoelectric conversion elements to the pads corresponding to the organic photoelectric conversion elements, respectively. The manufacturing process of the photoelectric conversion substrate is performed by dividing into, for example, first to fifth sub processes as follows.

In the first sub process, the optical filter section 210 and the passivation layer 211 covering up the optical filter section 210 are formed on a single side of a substrate 201A having a long plate shape, as shown in FIG. 16.

The substrate 201A can use materials as follows. (1) Inorganic glasses such as a soda-silica glass, a barium-strontium glass, a lead glass, an alumino silica glass, borosilicate glass, a barium borosilicate glass, a silica glass, a no alkali glass, and a fluoride glass, (2) Organic macromolecular compounds such as a polyethylene terephthalate, a polycarbonate, a polymethyl methacrylate, a polyether sulfone, a polyvinyl fluoride, a polypropylene, polyethylene, a polyacrylate, an amorphous polyolefin, and a fluorine based resin. (3) Chalcogenide glasses such as As₂S₃, As₄₀S₁₀, and S₄₀Ge₁₀. (4) Metallic oxides such as a zinc oxide, a niobium oxide, a tantalum oxide, a silicon oxide, a hafnium oxide, and a titanium oxide; and metal nitrides such as silicon nitride. (5) Transparent substrate materials colored by a pigment and the like, (6) Metal materials processed by an insulation treatment on their surface. In addition, it is also possible to use a material transmitting only specific wavelength light, a material converting incident light into specific wavelength light by using a function of light-to-light conversion, and the like. The transparent substrate 1 can employ a laminated structure where a plurality of substrate materials are laminated other than a single layer structure.

Here, the case of obtaining the photoelectric conversion device 230 (See FIG. 9) as described in Embodiment 3 will be described, and thus a transparent substrate is used as the substrate 201A. Hereinafter, the substrate 201A is referred to as ‘transparent substrate 201’.

The optical filter section 210 is formed by patterning a layer, which is made of organic composition (for example, color resin) colored by coloring material such as desired pigment or dye, in a predetermined shape by a method of photolithography. In addition, the optical filter section 210 can be formed by coating the desired organic composition colored by the coloring materials in a predetermined pattern by methods such as a printing method, an inkjet method, and a deposition method or by accumulating the desired organic composition on a predetermined location by an electrodeposition method.

On the other hand, the passivation layer 211 is preferably superior to not only heat resistance and solvent resistance, but also flatness, adhesion, transparency, light resistance, metachromasy, preservation stability, and the like. The passivation layer 211 can use raw materials that are light curing or thermosetting resin compositions such as an acryl base, an epoxy base, a polyimide base, a siloxane base, and an alkyl base. When the passivation layer 211 is made from the light curing or thermosetting resin compositions, a coating layer is formed by coating the resin composition in a method such as spin coat, the coating layer is patterned in a predetermined shape after being half-cured by irradiating a predetermined wavelength light to the coating layer or by performing a heat process, and then the coating layer is completely cured by the light irradiation or the heat process.

In the second sub process, the anodes 212r, 212g, and 212b, the read-out wires 204, the first wires 207 (which is not shown in FIG. 17), and the second wires 208 constituting the organic photoelectric conversion elements are formed, as shown in FIG. 17.

These anodes 212r, 212g, and 212b and the wires (the read-out wire 204, the first wire 207, and second wire 208) can use materials as follows. (1) Transparent conduction oxides such as an indium tin oxide (ITO: coating type ITO is also included), a tin oxide, a zinc oxide, an indium zinc oxide, an antimony doped tin oxide, and an aluminum doped zinc oxide. (2) Films of metals such as an aluminum, a copper, and a titanium, or metal films such as a mixed film and a laminated film of these metals. (3) Conductive high polymers such as a polypyrrole, a polyethylenedioxythiophene (hereinafter, it is refer to as ‘PEDOT’), polyphenylenevinylene (hereinafter, it is refer to as ‘PPV’), and a polyfluorene.

For example, a basis film for forming the anodes 212r, 212g, and 212b and the wires is formed by using a physical gas-phase deposition method such as a sputtering method or a vacuum deposition method (a resistance heating deposition method, an electron beam deposition method, or the like) or various polymerization methods (an electric field polymerization method or the like) in accordance with the material thereof. Then, the anodes 212r, 212g, and 212b and the wires are formed by patterning the basis film in a predetermined shape by a lithography method (a photolithography method, an electron beam lithography method, or the like) and an etching method. Accordingly, it is also possible to directly form the anodes 212r, 212g, and 212b and the wires in a desired shape by a physical gas-phase deposition method or a polymerization method of using a predetermined mask.

These anodes 212r, 212g, and 212b and the wires may be formed to have a single layer structure or a laminated layer structure. In order to secure sufficient conductivity or prevent the organic photoelectric conversion layer 213 (See FIG. 10) from irregular light incidence caused by surface unevenness of the transparent substrate 201, it is preferred that a film thickness thereof be 201 nm or more. In addition, in order to secure sufficient transparency of the anodes 212r, 212g, and 212b, it is preferable that that the film thickness thereof be 500 nm or less.

In the third sub process, the pads 217r, 217g, and 217b connected to the read-out wire 204 and a pad 223 connected to the second wire 208 (which is not shown in FIG. 18) is formed as shown in FIG. 18. When it is necessary to provide the pad connected to the first wire 207, the pad may be formed in the third sub process.

The pads are formed by laminating conductive materials such as gold, aluminum, and ITO on a predetermined position by using a physical gas-phase deposition method. Alternatively, the pads are formed by coating and curing a conductive paste containing gold, aluminum, ITO, and the like on a predetermined position.

In the fourth sub process, an insulation layer 219A that is a basis of the insulation layer 219 (See FIG. 10) is formed as shown in FIG. 19. The insulation layer 219A preferably has a resistance of 1×10⁹ Ωcm or more. The insulation layer 219A is made of an organic material such as light curing resin or an inorganic material such as silicon nitride. When the insulation layer 219A is made of the organic material, light-shielding ability may be given by containing a desired color material in the organic material. A method of forming the insulation layer 219A is appropriately selected from the coating method, the spin coat method, the physical gas-phase deposition method, chemical gas-phase deposition method, and the like, in accordance with the material.

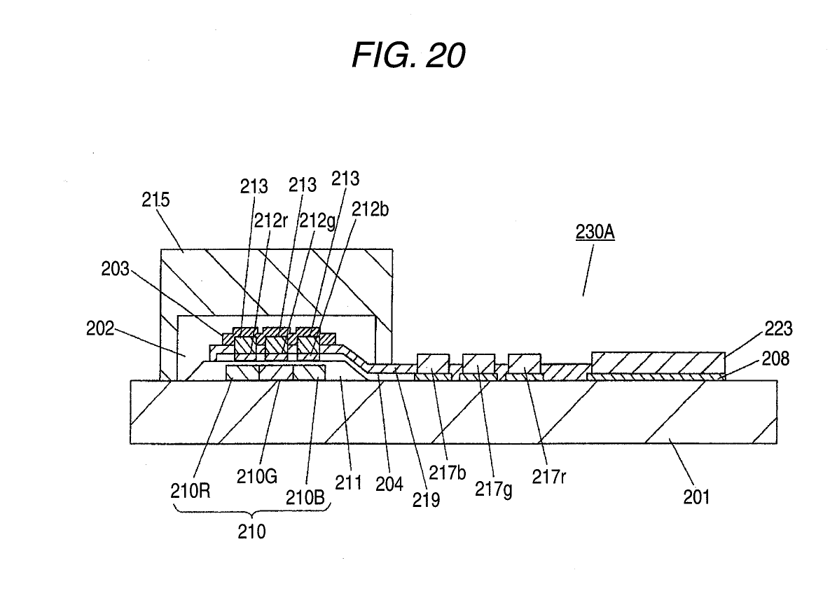

In the fifth sub process, after the insulation layer 219 is formed by patterning the insulation layer 219A formed in the fourth sub process, the organic photoelectric conversion layer 213 and the cathode 203 are formed on the transparent substrate 201, and the sealing section 215 is disposed to cover up the organic photoelectric conversion layer 213 and the cathode 203, as shown in FIG. 20.

The insulation layer 219 is formed by, for example, patterning the aforementioned insulation layer 219A in a predetermined shape by a lithography method (a photolithography method, an electron beam lithography method, or the like).

The organic photoelectric conversion layer 213 is made of, for example, an electron-donating organic material and an electron-accepting organic material. These electron-donating organic material and electron-accepting organic material may be formed in a mixture state or may be formed in a separation state.

Here, the ‘mixture’ means a state where a liquid phase or a solid phase material is put in a container, a solvent is added thereto as occasion demands, and then those are mixed by agitation and the like. The meaning of the ‘mixture’ includes a state where the mixed material is coated by the spin coat method or the inkjet method. In addition, the mixed state of the electron-donating organic material and electron-accepting organic material does not need to uniform, may be non-uniform state, and a part thereof may form the mixture. Meanwhile, when the electron-donating organic material and the electron-accepting organic material are separated from each other, the layers may not be separated from each other completely, and these layers may form the mixed state in the interface between a layer including the electron-donating organic material and a layer including the electron-accepting organic material. For example, by forming the layer including the electron-donating organic material and the layer including the electron-accepting organic material in different methods from each other, it is possible to obtain the organic photoelectric conversion layer 13 in which these layers are completely separated from each other. The detailed examples of the electron-donating organic material and the electron-accepting organic material will be described later.

The organic photoelectric conversion layer 213 can be formed by a vacuum process such as the vacuum deposition method or the sputtering method or a wet process such as the spin coat method, a dipping method, or the inkjet method in accordance with the organic materials used therein. When the organic photoelectric conversion layer 213 is formed by the wet process, it becomes easy to obtain the photoelectric conversion device 230 with low cost and high productivity.

The cathode 203 preferably uses a material capable of effectively discharging the electron that is generated from the organic photoelectric conversion layer 213. The material used therein includes a metal such as aluminum, indium, magnesium, titanium, silver, calcium, strontium, tungsten, chromium, barium, and nickel; an alloy containing these metals; a conductive oxide or a conductive fluoride containing these metals; or the like. In order to increase photoelectric conversion efficiency in the organic photoelectric conversion layer 213, it preferred that the cathode 203 is formed of a conductive material having high reflectance so as to contrive the photoelectric conversion by supplying again the organic photoelectric conversion layer 213 with light which reaches the cathode 203 without contriving the photoelectric conversion.

Likewise the aforementioned anodes 212r, 212g, and 212b, the cathode 203 may be formed in a single layer structure and may be formed in a laminated structure. The cathode 203 can be formed by the physical gas-phase deposition method such as the resistance heating deposition method, the electron beam deposition method, or the sputtering method.

The sealing section 215 uses a desired inorganic or organic material such as a glass or a resin having desired vapor transmittance and oxygen transmittance. For example, the sealing section 215 can be obtained by forming a concave portion on a flat plate made of the desired inorganic or organic material and patterning the flat plate in a boxy film shape. The sealing section 215 is fixed on the transparent substrate 201 by an inorganic adhesive such as a soft solder having the desired vapor transmittance and the oxygen transmittance or an organic adhesive such as a light curing adhesive, a thermosetting adhesive, or a two component type adhesive.

In addition, the sealing section can be formed by forming an inorganic film made of a silicon oxide, a silicon oxynitride, an aluminum oxide, a silicon nitride, a lithium fluoride, or the like so as to cover up the cathode 203 and the organic photoelectric conversion layer 213; a glass film made by a sol-gel method; or an organic film made of a thermosetting resin, a light curing resin, a silane based high polymer material having a sealing effect.

With such a configuration, the sealing section is formed, and thus a photoelectric conversion substrate 230A including the plurality of organic photoelectric conversion elements is obtained.

In addition, as for the aforementioned electron-donating organic material, the organic photoelectric conversion layer 213 uses the following materials. (1) A polymer and a derivative thereof such as a phenylenevinylene and a derivative thereof, a fluorene and a derivative thereof (a fluorene based copolymer (POF66, P1F66, PFPV, or the like) of which structure has a quinoline group, a pyridine group, or the like), an arylamine polymer containing a fluorene, a carbazole and a derivative thereof, an indole and a derivative thereof, a pyrene and a derivative thereof, a pyrrole and a derivative thereof, a picoline and a derivative thereof, a thiophene and a derivative thereof, an acethylene and a derivative thereof, or a diacethylene and a derivative thereof. (2) A group of high polymer materials which is collectively referred to as dendrimer. (3) A porphyrin compound such as a porphine, a tetraphenylporphine copper, a phthalocyanine, a copper phthalocyanine, or a titanium phthalocyanine oxide. (4) An aromatic tertiary amine such as 1,1-bis(4-(di-p-tolylamino)phenyl) cyelohexane, 4,4′,4″-trimethyltriphenylamine, N,N, N′,N′-tetrakis (p-tolyl)-p-phenylenediamine, 1-(N,N-di-p-tolylamino)naphthalene, 4,4′-bis(dimethylamino)-2,2′-dimethyltriphenylmethane, N,N, N′,N′-tetraphenyl-4,4′-diaminobiphenyl, N,N′-diphenyl-N,N′-di-m-tolyl-4,4′-diaminobiphenyl, N-phenylcarbazole. (5) A stilbene compound such as 4-di-p-tolylaminostilbene, 4-(di-p-tolylamino)-4′-(4-(di-p-tolylamino)styryl)stilbene.

In addition, it is also possible to use a triazole and a derivative thereof, an oxadiazole and a derivative thereof, imidazole and a derivative thereof, a polyarylalkane and a derivative thereof, a pyrazolene and a derivative thereof, pyrazolone and a derivative thereof, a phenylenediamine and a derivative thereof, an arylamine and a derivative thereof, an amino substitution chalcone and a derivative thereof, an oxazole and a derivative thereof, a styryl anthracene and a derivative thereof, a fluorenone and a derivative thereof, a hydrazine and a derivative thereof, a silazane and a derivative thereof, a polysilane based aniline based copolymer, a tyrylamine compound, an aromatic dimethylidyne based compound, a poly3-methylthiophene or the like. Additionally, absorption wavelength characteristics of the electron-donating organic material can be adjusted by modifying the material chemically.

On the other hand, as for the aforementioned electron-accepting organic material, the organic photoelectric conversion layer 213 uses not only low and high polymer materials that are the same as the aforementioned electron-donating organic material but also the following materials. As the materials, it is possible to use a polymer having a repetition unit such as compounds (i) to (vi), that is, (i) oxadiazole and a derivative thereof such as 1,3-bis(4-tert-butylphenyl-1,3,4-oxadiazolyl)phenylene, (ii) fluorene and a derivative thereof, (iii) anthraquinodimathane and a derivative thereof, (iv) diphenylquinone and a derivative thereof, (v) fullerene and a derivative thereof ([5,6]-phenyl C61 methyl butyrate ester, [6,6]-phenyl C61 methyl butyrate ester, or the like), (Vi) a copolymer having carbon nanotube and a derivative thereof as its repetition unit. Alternatively, it is possible to use a copolymer of compounds of (i) to (vi) and other monomers as the aforementioned electron-accepting organic material.

Additionally, the high polymer material of the first group referred to as dendrimer may be used. Additionally, absorption wavelength characteristics of the electron-accepting organic material can be adjusted by modifying the material chemically.

### <Mounting Process>

In a mounting process, the plurality of organic photoelectric conversion elements formed on the transparent substrate constituting the aforementioned photoelectric conversion substrate is divided into a plurality of groups in the longitudinal direction of the transparent substrate, and the read-out circuit sections are disposed on the plurality of groups, respectively. The read-out circuit sections reads out the signal electric charges via the read-out wires and the pads from the organic photoelectric conversion elements constituting the corresponding groups, respectively, and are mounted on the transparent substrate.

As for the read-out circuit sections 205a to 205d (See FIG. 9), for example, a semiconductor bare chip in which a predetermined integrated circuit is formed on a single crystal silicon substrate is used. As might be expected, a packaged semiconductor chip can be used as the read-out circuit section.

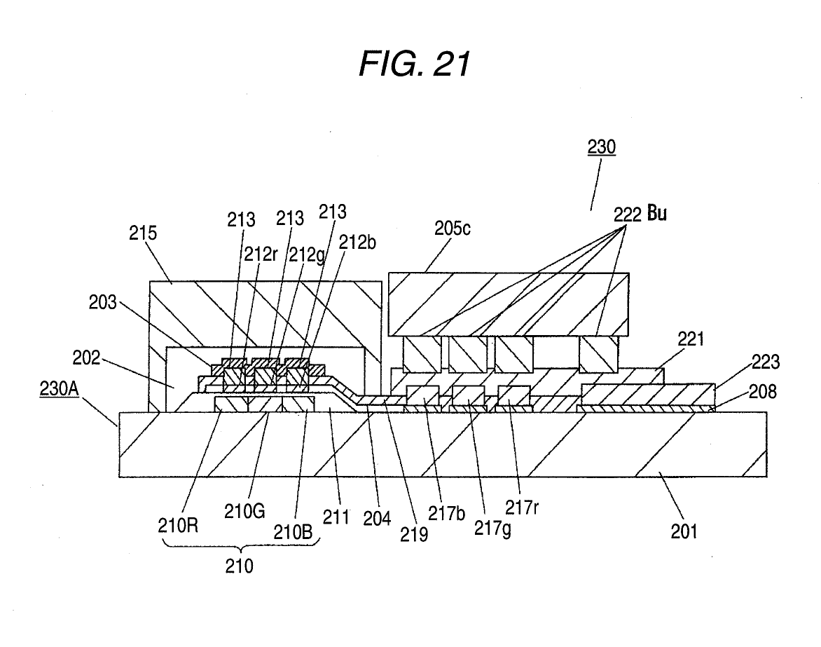

As shown in FIG. 21, the anisotropy conduction film 221 can be preferably used in mounting the read-out circuit sections 205a to 205d in FIG. 20, only the one read-out circuit section 205c is shown) on the transparent substrate 201 constituting the photoelectric conversion substrate 230A. By using the anisotropy conduction film 221, it is possible to mount the read-out circuit sections 205a to 205d on the small mounting area, and thus it becomes easy to decrease the size of the photoelectric conversion device 230 (See FIG. 9). When the mounting area is sufficiently large, the photoelectric conversion device can be configured so that the read-out circuit sections are mounted on the transparent substrate by, for example, a wire bonding without using the anisotropy conduction film. The photoelectric conversion device 230 described in Embodiment 3 is obtained by performing this mounting process.

The photoelectric conversion device and the manufacturing method thereof according to the invention have been described by referring to two embodiments, but the invention is not limited to the embodiments as described above. Configurations other than the arrangement of the read-out circuit sections in the photoelectric conversion device according to the invention can be appropriately selected in accordance with a use of the photoelectric conversion device and performance required of the photoelectric conversion device.

For example, it is preferred that the transparent substrate 201 (See FIG. 10) have desired mechanical and thermal strength and be an insulation substrate transmitting light. However, the transparent substrate 201 may have some conductivity in accordance with a use of the photoelectric conversion device 230 or in the range of not disturbing an operation of the photoelectric conversion device 230.

In addition, it is possible to randomly determine whether the optical filter section 210 (See FIG. 10) is provided. When the optical filter section 210 is provided, the optical filter section 210 is disposed on each optical path of light incident on the plurality of organic photoelectric conversion elements, and transmits light having a predetermined wavelength band in the incident light. The optical filter section 210 may be constituted of not only three optical filters 210R, 210G, and 210B of primary colors but also three optical filters (a cyan filter, a magenta filter, and a yellow filter) of complementary colors or optical filters of a single color. In addition, the optical filter section 210 can be constituted of holographic elements having the same optical function as these optical filters.

The array structure of the organic photoelectric conversion element in the photoelectric conversion section 202 (see FIG. 9) employs three organic photoelectric conversion elements as a repetition unit, but it may be possible to employ one organic photoelectric conversion element, two organic photoelectric conversion elements, or four or more organic photoelectric conversion elements as a repetition unit. The size of each organic photoelectric conversion element in a top view is appropriately selectable in accordance with a use or performance of the photoelectric conversion device 230.

In the organic photoelectric conversion elements, the light curing resin layer may be formed so as to cover up an inner margin portion of each of the anodes 212r, 212g, and 212b as viewed from the top. The light curing resin layer is formed by patterning a desired light curing resin composition layer in a predetermined shape by a lithography method. Since this method does not use an etching process, it is easy to increase shape accuracy thereof. In addition, by forming the light curing resin in this manner, even when position accuracy or shape accuracy of the anodes 212r, 212g, and 212b is not increased, effective areas of the organic photoelectric conversion elements can be determined by the light curing resin layer. As a result, when a linear image sensor is configured by using the photoelectric conversion device according to the invention, it becomes easy to obtain high quality image data. The light curing resin layer may be formed with the read-out wires by using the material of the insulation layer for covering up the read-out wires and may be formed independent of the insulation layer for covering up the read-out wires.

A positive pole buffer layer made of a material having a work function higher than a work function of the anodes 212r, 212g, and 212b and lower than a work function of the aforementioned electron-donating material can be interposed between the anode 212r, 212g, or 212b and the organic photoelectric conversion layer 213 thereon in each organic photoelectric conversion element, as occasion demands. Likewise, a negative pole buffer layer made of a material having a work function higher than a work function of the aforementioned electron-accepting material such as a metal fluoride like a lithium fluoride or metal oxide and lower than a work function of the cathode 203 can be interposed between the organic photoelectric conversion layer 213 and the cathode 203 thereon, as occasion demands.

The insulation layer 219 for covering up the read-out wires 204 is formed in a state of contacting the pads 217r, 217g, and 217b on lateral faces of the pads 217r, 217g, and 217b, but the insulation layer 219 may be formed at a predetermined distance, for example, at a distance less than diameter of a conductive particle in the anisotropy conduction film away from the pads 217r, 217g, and 217b. When the insulation layer 219 is formed in this manner, even though there are some manufacturing errors on a position of the insulation layer 219, it is possible to electrically connect the bump Bu of the read-out circuit sections 205a to 205d with the pad 217r, 217g, or 217b at the time of mounting the read-out circuit sections 205a to 205d.

The read-out wire 204 (see FIG. 9 or 10), the first wire 207, and the second wire 208 are formed of the same material as the anodes 212r, 212g, and 212b as described above, but those may be formed of other conductive material such as gold, chrome, or copper. In addition, those may be formed of a mixture of plural kinds of the conductive material or a laminated material in which each layer has a different conductive material from each other.

Mounting the read-out circuit sections 205a to 205d on the transparent substrate 201 may be performed by using an anisotropy conduction adhesive without using the anisotropy conduction film. In addition, it is also possible to perform the mounting process by using the wire bonding, as previously described. The number of the read-out circuit sections mounted on the transparent substrate 201, that is, the number of the organic photoelectric conversion element groups is appropriately selectable in accordance with the total number of the organic photoelectric conversion elements or a reading speed of the linear image sensor configured by using the photoelectric conversion device of the invention. In order to increase the reading speed, it is preferred that three or more read-out circuit sections be mounted on the transparent substrate 201. Moreover, the photoelectric conversion device and the manufacturing method thereof according to the invention can be changed, modified, or combined in various forms. Hereinafter, detailed contents of the invention will be further described with reference to examples.

### EXAMPLE

### Example 1

First, a soda glass substrate having a long plate shape was prepared as the transparent substrate. An ITO film having a thickness of 150 nm was deposited on this soda glass substrate by a sputtering method, a resist film having a thickness of 1 μm was formed by coating a resist material (Tokyo ohka Inc. OFPR-800 (product name)) on the ITO film by a spin coat method, an exposure, a development, and a post-bake processes were selectively performed on the resist film after a pre-bake process was performed on the resist film, and so a predetermined shaped resist pattern was obtained. The transparent substrate (soda glass substrate) having the resist pattern formed thereon was immersed in 50% hydrochloric acid aqueous solution of 60 degrees Celsius and an etching process was performed on the ITO film on which the resist pattern was not formed.

Then, after the resist pattern was removed, there were obtained a lot of the anodes (the anodes used for the organic photoelectric conversion elements) which are arranged in a matrix shape of 3 rows and 7500 columns, the read-out wires connected to the anodes, respectively, and the plurality of second wires for connecting the read-out circuit sections to each other. A pitch of the anodes neighboring to each other in a row direction (the longitudinal direction of the transparent substrate) is 0.042 mm, and a distance thereof is 0.005 mm. A pitch and a distance of the anodes neighboring to each other in a column direction (a direction orthogonal to the longitudinal direction of the transparent substrate, as viewed from the top) is also 0.042 mm and 0.005 mm, respectively.

Next, a copper (Cu) film having a thickness of 1 μm was deposited by the physical gas-phase deposition method on the transparent substrate having the anodes and the read-out wires formed thereon, a resist film having a thickness of 2 μm was formed by coating a resist material (Tokyo ohka Inc. OFPR-800 (product name)) on the copper film by a spin coat method, an exposure, a development, and a post-bake processes were selectively performed on the resist film after a pre-bake process was performed on the resist film, and so a predetermined shaped resist pattern was obtained. The transparent substrate (soda glass substrate) having the resist pattern formed thereon was immersed in 50% phosphoric acid aqueous solution of room temperature and an etching process was performed on the copper film on which the resist pattern was not formed. Then, after the resist pattern was removed, there were obtained the plurality of pads located on ends (the end of a side which is not connected to the anode) of the read-out wires, the read-out circuit section, and the plurality of first wires for connecting the circuit board.

Next, a resin composition layer having a thickness of 1 μm was formed by coating a polyimide based photosensitive resin composition (Toray Industries Inc. PN (product name)) in a spin coat method on the transparent substrate having the pads and the first wires formed thereon, an exposure, a development, and a post-bake processes were selectively performed on the resin composition layer after a pre-bake process was performed on the layer, and so the insulation layer for covering up the read-out wires, the first wires, and the second wires was obtained. The insulation layer electrically separates the read-out wires neighboring to each other and electrically separates the read-out wires from organic photoelectric conversion elements other than the organic photoelectric conversion elements corresponding to the read-out wires. The insulation layer was formed in the state of contacting the pads on lateral faces of the pads.

Next, a mixture between a poly (3,4-ethylenedioxythiophene) and a polystylenesulfonate was dropped onto the transparent substrate via a filter having a mesh of 0.45 μm and was uniformly coated by the spin coat method. By heating the mixture in a clean oven of 200 degree Celsius for 30 minutes, the positive pole buffer layer for covering up the anodes was formed.

Then, chlorobenzene solution containing poly(2-methoxy-5-(2′-ethylhexyloxy)-1,4-phenylenevinylene) and [5,6]-phenyl C61 methyl butyrate ester with a weight ratio of 1 to 4 was coated on the buffer layer of the positive pole side by the spin coat method, was heated in the clean oven of 100 degree Celsius for 30 minutes, and so the organic photoelectric conversion layer having a thickness of 100 nm or so was formed on the anodes.

Continuously, in an inner portion, which is decompressed to vacuum of 0.27 mPa (2×10⁻⁶ Torr) or less, of the resistance heating deposition device, a lithium fluoride film as the negative pole buffer layer having a thickness of 2 nm and an aluminum film as the cathode having a thickness of 100 nm or so were deposited in the sequence on the organic photoelectric conversion layers. By forming this cathode, there were formed a number of the anodes (ITO film), the positive pole buffer layers, the organic photoelectric conversion layers, the negative pole buffer layers, the organic photoelectric conversion elements including the cathodes.

Then, by preparing a boxy film shaped object made of glass as a sealing section, the boxy film shaped object was fixed on the transparent substrate by an epoxy based light curing adhesive so as to cover up the organic photoelectric conversion elements, and the four read-out circuit sections were formed by the flip chip bonding on the transparent substrate with the anisotropy conduction film interposed therebetween. Each read-out circuit section was constituted of the semiconductor bare chips having the predetermined integrated circuits formed therein.

By performing the mounting process of the four read-out circuit sections in this manner, the targeted photoelectric conversion device was obtained. The photoelectric conversion device has a structure in which the optical filter section 210 and the passivation layer 211 are removed from the photoelectric conversion device 230 shown in FIG. 10.

### Example 2

After the optical filter section and the passivation layer for covering up the optical filter section were provided on the transparent substrate made of the no alkali glass, the same process as Example 1 was performed except for forming the anodes (the anodes used for the organic photoelectric conversion elements) on the passivation layer, and so the organic photoelectric device having the same structure as the photoelectric conversion device 230 shown in FIG. 10 was obtained.

At this time, in order to form the optical filter section, first, a coating film is formed by coating a desired color resin on the transparent substrate (the no alkali glass substrate), the coating film was exposed through a photo mask after the coating film was pre-baked at 100 degrees Celsius, color resin layers patterned in a stripe shape were obtained by performing the development process on each color resin of a red, a green, and a blue, and three pre-baked color resin layers having the film thickness of 2 μm were formed in a stripe shape in parallel. Then, by post-baking the three pre-baked color resin layers, the optical filter section including a red color filter, a green color filter, and a blue color filter was formed.

Additionally, in order to form the passivation layer, first, a coating film of the thermosetting resin composition was formed by a spin coat method so as to cover up the optical filter section, and a photo mask having a predetermined shape was formed on the coating film after the coating film was dried. Next, the exposure process was selectively performed on the dried coating film by using the photo mask, the development process was performed thereon, and the coating film was baked at 200 degrees Celsius. Therefore, the passivation layer for covering up a surface and a lateral face of the optical filter section was formed. A thickness (the thickness upon optical filter section) of the passivation layer was about 2 μm, and a taper thereof is formed so as to be attached to the passivation layer in a lateral direction of the optical filter section.

### Example 3

When the same process as Example 2 was performed except for using an aluminum (Al) film having a thickness of 2 μm as a material of the pads and the first wires, the organic photoelectric device having the same structure as the photoelectric conversion device 230 shown in FIG. 10 was obtained. At this time, the aluminum film was formed by the physical gas-phase deposition method.

In the photoelectric conversion device obtained by such a method, there was a big difference between a surface position of the pads and a surface position of the insulation layer for covering up the read-out wires when the a surface position of the transparent substrate was set by a reference position, as compared with the photoelectric conversion device obtained in Example 2. Hence, when the read-out circuit section was mounted on the transparent substrate with the anisotropy conduction film interposed therebetween, the read-out circuit section could be sufficiently held down to the transparent substrate side without being disturbed by the insulation layer. As a result, it was easy to completely connect the bump Bu of the read-out circuit section with the bump on the transparent substrate

### Example 4

In order to provide the passivation layer for covering up the optical filter section on the transparent substrate, the same process as Example 3 was performed except that baking temperature of the thermosetting resin composition was set by 250 degrees Celsius, a thickness of the passivation layer was about 1.8 μm, the insulation layer for covering up an inner margin portion of the anodes (the anodes used for the organic photoelectric conversion elements) of the top view and the resin composition layer which was the basis of the insulation layer were simultaneously formed in order to obtain the insulation layer for covering up the first wires and the second wires, and the insulation layer for covering up the read-out wires, the first wires, and the second wires were formed so as to contact lateral faces of the pads. Therefore, the organic photoelectric device having the same structure as the photoelectric conversion device 230 shown in FIG. 10 was obtained.

In the photoelectric conversion device obtained by such a method, the insulation layer was formed on the anodes in each organic photoelectric conversion element by the lithography method, and thus shape accuracy thereof was high. Hence, an effective area of the organic photoelectric conversion elements was easily set in an allowable design range. In addition, it was possible to reduce unstable current generated form the ends (the edge portions) of the anodes. In addition, the insulation layer for covering up the wires contacts the pads on the lateral faces of the pads. Therefore, the conductive particle in the anisotropy conduction film did not permeate into between the insulation layer and the pads, and it was hard to form conduction in a undesired location.

### Example 5

The same process as Example 4 was performed except that the insulation layer for covering up the read-out wires, the first wires, and the second wires was formed at a distance less than 1 μm or so (the distance less than a diameter of the conductive particle in the anisotropy conduction film) away from the lateral faces of the pads. Therefore, the organic photoelectric device having the same structure as the photoelectric conversion device 230 shown in FIG. 10 was obtained.

In the photoelectric conversion device obtained by such a method, the insulation layer was distanced form the lateral faces of the pads. Therefore, even though there were some manufacturing errors on a position of the insulation layer, it was possible to electrically connect the bump Bu of the read-out circuit sections with the pad.

### Example 6

The same process as Example 4 was performed except that a black resist (Tokyo ohka Inc. CFPR BK 8311RE (product name)) was used as a material of the insulation layer for covering up the read-out wires, the first wires, and the second wires. Therefore, the organic photoelectric device having the same structure as the photoelectric conversion device 230 shown in FIG. 10 was obtained.

In the photoelectric conversion device obtained by such a method, the insulation layer has a light-shielding property, and thus photoelectric conversion was suppressed in locations other than locations in which the organic photoelectric conversion layer was directly contacted with the anodes. Consequently, the photoelectric conversion was prevented in locations other than locations designed as the organic photoelectric conversion elements.

The photoelectric conversion device according to the invention can be used as the photoelectric conversion device in the linear image sensor.

This application is based upon and claims the benefit of priority of Japanese Patent Application No 2006-242459 filed on Jun. 9, 2007, Japanese Patent Application No 2006-251064 filed on Sep. 15, 2006, the contents of which are incorporated herein by reference in its entirety.

What is claimed is:

1. An image sensor comprising:
a substrate;
a plurality of photoelectric converters, mounted on the substrate, for each of which a photoelectric conversion layer is formed of an organic compound layer and is sandwiched between an anode and a cathode so as to perform photoelectric conversion based on incident light;
drive circuits for detecting output provided by a signal current generated by the photoelectric converters, and for reading signal charges; and
a wiring for electrically connecting the photoelectric converters and the drive circuits,
wherein, for the plurality of the photoelectric converters that form one read pixels, the size of a photoelectric conversion area differs in accordance with a sensitivity of each of the plurality of photoelectric converters.

2. The image sensor according to claim 1, wherein, for the plurality of photoelectric converters, a photoelectric conversion area is increased for a photoelectric converter having a low sensitivity.

3. The image sensor according to claim 1, wherein, for the plurality of photoelectric converters, a distance from the drive circuits is increased for a photoelectric converter having a low sensitivity.

4. The image sensor according to claim 1, wherein the plurality of photoelectric converters are located in rows perpendicular to a direction in which input terminals of the drive circuits are arranged.

5. The image sensor according to claim 1,
wherein, when I (lux) denotes the maximum illuminance of light that enters the photoelectric converters, and α[volt/(lux·time)] denotes a sensitivity, the plurality of photoelectric converters are so arranged that a photoelectric converter having a small product of I and α is located at a distance from the drive circuits, with a photoelectric conversion area being increased.

6. The image sensor according to claim 1,
wherein the plurality of photoelectric converters are devices for reading red light, green light and blue light; and
wherein a photoelectric converter that performs photoelectric conversion for red light is located farthest from the drive circuits with the photoelectric conversion area being larger than the photoelectric conversion areas for photoelectric converters of the other colors.

7. The image sensor according to claim 1, wherein the drive circuits are IC chips formed of a single crystal silicon transistor, or thin film transistors formed of polycrystal silicon or amorphous silicon formed on the substrate.

8. The image sensor according to claim 5,
wherein the drive circuits are located on the substrate to sandwich the plurality of photoelectric converters that are arranged in rows, and include two thin film transistors made of polycrystal silicon or amorphous silicon; and
wherein, among the plurality of photoelectric converters, a photoelectric converter having a smallest product of I and α is located at a position farthest from the two thin film transistors in an area that is sandwiched by the two thin film transistors.
